(19) United States
(12) Patent Application Publication
(10) Pub. No.: US 2026/0004856 A1
(43) Pub. Date: Jan. 1, 2026

(54) METHOD OF READING DATA FROM NONVOLATILE MEMORY DEVICE AND NONVOLATILE MEMORY DEVICE PERFORMING THE SAME

(71) Applicant: SAMSUNG ELECTRONICS CO., LTD., Suwon-si (KR)

(72) Inventors: Sangwon Park, Suwon-si (KR); Garam Kim, Suwon-si (KR); Taeyun Lee, Suwon-si (KR); Ilhan Park, Suwon-si (KR); Sunghoon Jung, Suwon-si (KR)

(21) Appl. No.: 19/255,539

(22) Filed: Jun. 30, 2025

(30) Foreign Application Priority Data
Jul. 1, 2024 (KR) 10-2024-0086086
Aug. 19, 2024 (KR) 10-2024-0110392

(51) Int. Cl. G11C 16/26; G11C 16/04; G11C 16/08

(52) U.S. Cl. CPC G11C 16/26; G11C 16/08; G11C 16/0483

(57) ABSTRACT

In a method of reading data from a nonvolatile memory device, a first sensing operation is performed based on a first read command. While pending reception of a second read command after the first read command, voltages of a plurality of wordlines are controlled such that a voltage of a selected wordline and voltages of unselected wordlines among the plurality of wordlines have a same voltage level. A recovery operation is omitted when the second read command is received within a reference time interval. A second sensing operation is performed based on the reception of the second read command.

### CROSS-REFERENCE TO RELATED APPLICATION

This application claims priority under 35 USC § 119 to Korean Patent Application No. 10-2024-0086086 filed on Jul. 1, 2024, and to Korean Patent Application No. 10-2024-0110392 filed on Aug. 19, 2024, in the Korean Intellectual Property Office (KIPO), the contents of which are herein incorporated by reference in their entirety.

### BACKGROUND

Semiconductor memory devices may be classified into volatile memory devices and nonvolatile memory devices based on whether the semiconductor memory devices lose stored data when disconnected from a power supply. Volatile memory devices may read and write data at a higher speed than nonvolatile memory devices but lose stored data when the power supply is disconnected, while nonvolatile memory devices may retain stored data in the same condition.

In a nonvolatile memory device, a setup time interval may be performed on various types of lines before write and read operations. In addition, a recovery time interval may be performed as an initialization operation on the various types of lines after the write and read operations. However, the setup time interval and the recovery time interval may increase the amount of time used for an entire operation of the nonvolatile memory device and may also increase power consumption of the nonvolatile memory device.

### SUMMARY

In some implementations of the present disclosure, a method of reading data from a nonvolatile memory device capable of decreases the amount of time used for an entire operation and power consumption.

In some implementations of the present disclosure provides, a nonvolatile memory device performs the method of reading data.

In a first general aspect, a method of reading data from a nonvolatile memory device includes a first sensing operation performed based on a first read command. While pending reception of a second read command after the first read command, voltages of a plurality of wordlines are controlled such that a voltage of a selected wordline and voltages of unselected wordlines among the plurality of wordlines have a same voltage level. A recovery operation is omitted when the second read command is received within a reference time interval. A second sensing operation is performed based on the reception of the second read command.

In a second general aspect, a nonvolatile memory device includes: a memory cell array, a voltage generator and a control circuit. The memory cell array includes a plurality of memory cells connected to a plurality of wordlines. The voltage generator generates a plurality of driving voltages applied to the plurality of wordlines. The control circuit, by controlling operations of the memory cell array and the voltage generator, receives the first read command, performs a first sensing operation based on the first read command, while pending reception of a second read command after the first read command, controls voltages of a plurality of wordlines such that a voltage of a selected wordline and voltages of unselected wordlines among the plurality of wordlines have a same voltage level, receives the second read command, omits a recovery operation when the second read command is received within a reference time interval and performs a second sensing operation based on the second read command.

In a third general aspect, a method of reading data from a nonvolatile memory device includes receiving a first read command in a sequential read mode. A first sensing operation is performed based on the first read command. While pending reception of a second read command after the first read command, voltages of a plurality of wordlines are controlled such that a voltage of a selected wordline and voltages of unselected wordlines among the plurality of wordlines have a same voltage level by increasing a voltage level of the voltage of the selected wordline and decreasing voltage levels of the voltages of the unselected wordlines. The reception of the second read command is checked. A recovery operation is omitted when the second read command is received within a reference time interval. The recovery operation is performed in response to determining that the second read command is not received after the reference time interval elapses. A second sensing operation is performed based on the reception of the second read command. A pending time interval is terminated after a time interval elapses when the second read command is received before the time interval elapses from a start of the pending time interval.

In the disclosed method of reading data from the nonvolatile memory device and the nonvolatile memory device, while pending the reception of the next command in sequential operations, the voltage of the selected wordline and the voltages of the unselected wordlines may be controlled such that the voltage of the selected wordline and the voltages of the unselected wordlines have the same voltage level and the recovery operation may be omitted selectively. Accordingly, the amount of time used for a read operation and a latency of the read operation may decrease, and the read operation may be performed efficiently because the recovery operation does not need to be performed each time the read operation is performed. In addition, the power consumption of the nonvolatile memory device may be reduced by decreasing the voltage levels of the wordlines and omitting the recovery operation.

### BRIEF DESCRIPTION OF THE DRAWINGS

FIG. 1 is a flowchart illustrating an example of a method of reading data from a nonvolatile memory device.

FIG. 2 is a flowchart illustrating an example of omitting a recovery operation according to a reception condition of a second read command of FIG. 1.

FIG. 3 is a diagram for describing an example of a method of reading data from a nonvolatile memory device.

FIG. 4 is a block diagram illustrating an example of a nonvolatile memory device.

FIG. 5 is a perspective view of an example of a memory block included in a memory cell array in a nonvolatile memory device of FIG. 4.

FIG. 6 is a circuit diagram illustrating an equivalent circuit of a memory block described with reference to FIG. 5.

FIGS. 7A, 7B and 7C are diagrams for describing an example of a threshold voltage distribution of data stored in a nonvolatile memory device.

FIG. 8 is a flowchart illustrating an example of controlling voltages of a plurality of wordlines of FIG. 1.

FIGS. 9A, 9B, 10A, 10B, 11A, 11B, 12, 13A, 13B, 13C, 14A and 14B are diagrams for describing an example of a method of reading data from a nonvolatile memory device.

FIGS. 15 and 16 are flowcharts illustrating an example of a method of reading data from a nonvolatile memory device.

FIG. 17 is a block diagram illustrating an example of a nonvolatile memory device and a memory system including the nonvolatile memory device.

FIG. 18 is a cross-sectional view of an example of a nonvolatile memory device.

Like reference numerals refer to like elements throughout this application.

### DETAILED DESCRIPTION

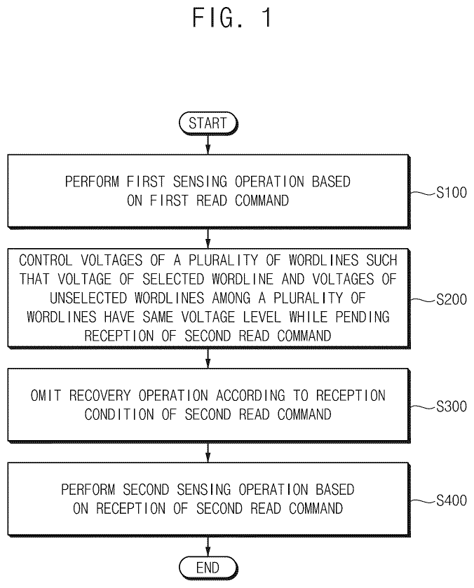

FIG. 1 is a flowchart illustrating an example of a method of reading data from a nonvolatile memory device.

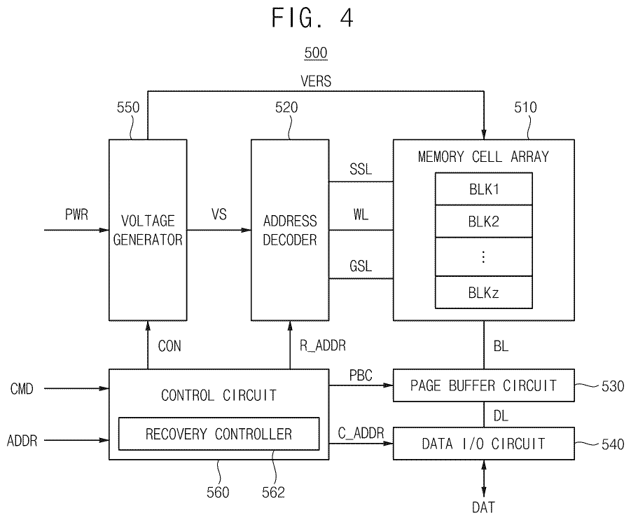

Referring to FIG. 1, the method of reading data from the nonvolatile memory device is performed by the nonvolatile memory device including a plurality of memory cells connected to a plurality of bitlines and a plurality of string selection lines. A structure of the nonvolatile memory device will be described with reference to FIG. 4.

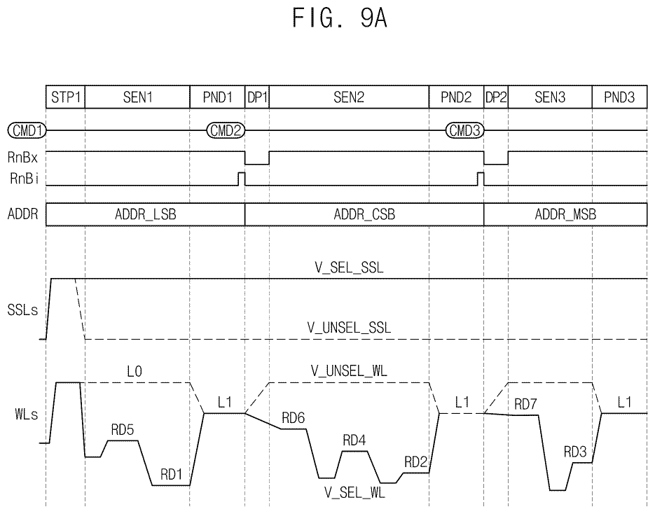

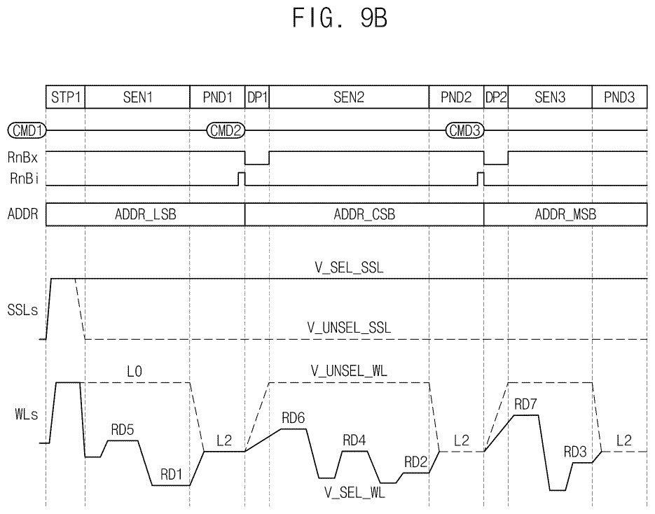

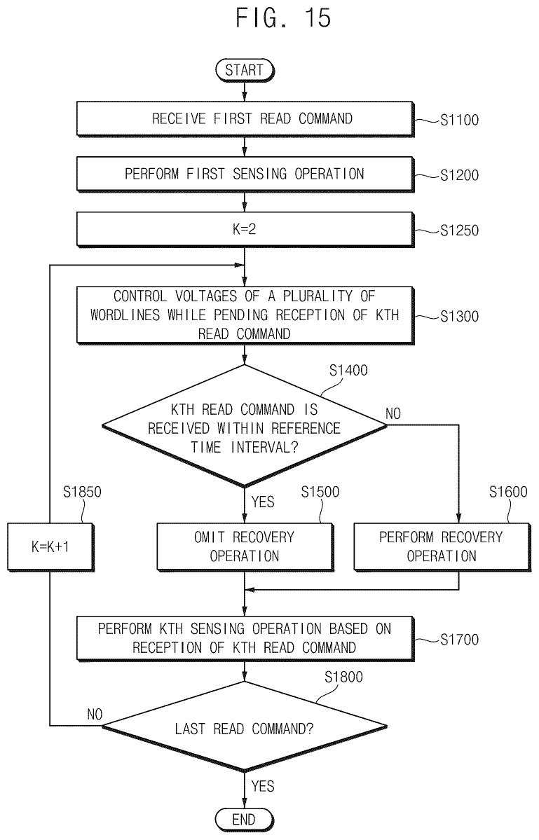

In the method of reading data from the nonvolatile memory device, a first sensing operation is performed based on a first read command (operation S100). For example, the first read command may be a command associated with a first memory cell connected to a first bitline among the plurality of bitlines and a first string selection line among the plurality of string selection lines, and the first sensing operation may represent an operation for reading data stored in the first memory cell. For example, as will be described with reference to FIGS. 9 and 15, an operation of receiving the first read command and a first setup operation for preparing the first sensing operation may be performed before operation S100.

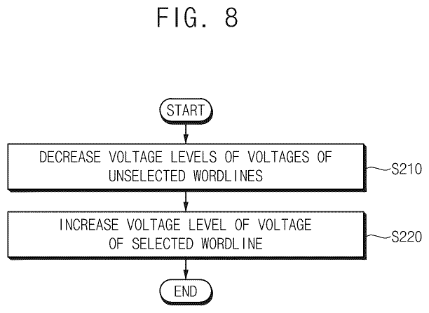

While pending reception of a second read command after the first read command, voltages of the plurality of wordlines are controlled such that a voltage of a selected wordline and voltages of unselected wordlines among the plurality of wordlines have the same voltage level (operation S200). For example, to have the same voltage level, a voltage level of the voltage of the selected wordline may increase, and voltage levels of the voltages of the unselected wordlines may decrease. Operation S200 will be described with reference to FIGS. 8 and 9.

In some implementations, a pending time interval for pending the reception of the second read command may be maintained for at least a predetermined time interval. For example, the pending time interval may be terminated after the predetermined time interval elapses even when the second read command is received before the predetermined time interval elapses from a start of the pending time interval.

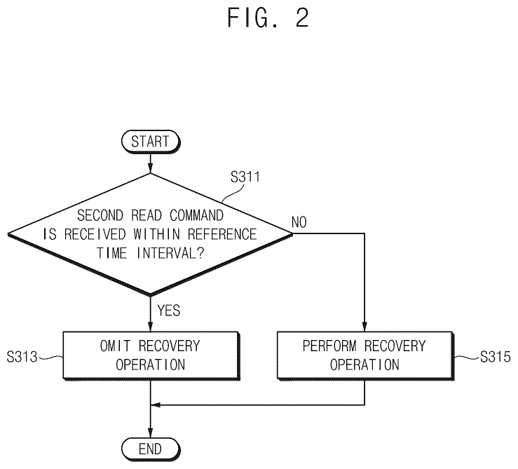

A recovery operation is omitted according to, e.g., in response to, a reception condition of the second read command (operation S300). For example, the recovery operation may be omitted when the second read command is received within a reference time interval, e.g., a predetermined time interval. The recovery operation may represent an operation of initializing lines connected to the first memory cell after the first sensing operation. Operation S300 will be described with reference to FIG. 2.

A second sensing operation may be performed based on the reception of the second read command (operation S400). Operation S400 may be similar to operation S100.

In some implementations, as will be described with reference to FIG. 9, the first read command and the second read command may be commands associated with the same memory cell connected to the same wordline and the same string selection line. For example, the second read command may be a command associated with the first memory cell connected to the first bitline and the first string selection line, and the second sensing operation may represent the operation for reading the data stored in the first memory cell.

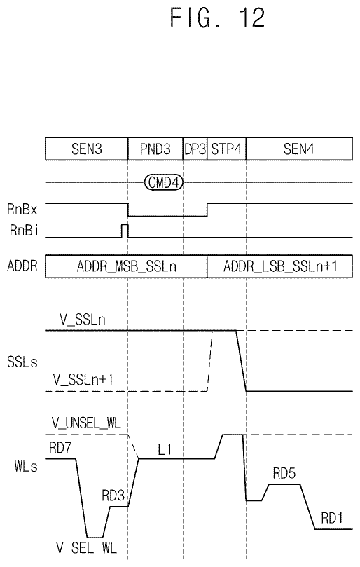

In some implementations, as will be described with reference to FIG. 12, the first read command and the second read command may be commands associated with different memory cells connected to different string selection lines. For example, the second read command may be a command associated with a second memory cell connected to a second string selection line different from the first string selection line among the plurality of string selection lines, and the second sensing operation may represent an operation for reading data stored in the second memory cell.

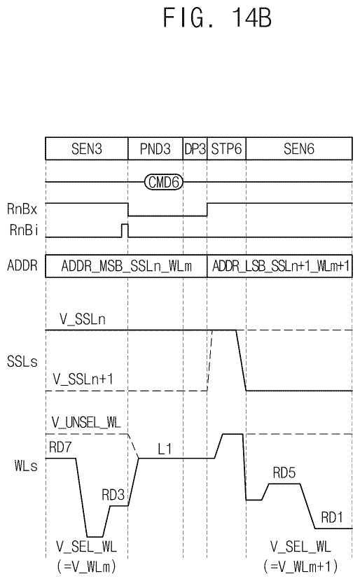

In some implementations, as will be described with reference to FIG. 14A, the first read command and the second read command may be commands associated with different memory cells connected to different wordlines. For example, the second read command may be a command associated with a third memory cell connected to a second bitline different from the first bitline among the plurality of bitlines, and the second sensing operation may represent an operation for reading data stored in the third memory cell.

In some implementations, as will be described with reference to FIG. 14B, the first read command and the second read command may be commands associated with different memory cells connected to different string selection lines and different wordlines.

In some implementations, the method of reading data from the nonvolatile memory device may be performed when the nonvolatile memory device operates in a sequential read mode. For example, operations S100, S200, S300 and S400 may be performed associated with a read operation processed continuously/sequentially. The sequential read mode may be referred to as a sequential cache read mode.

FIG. 2 is a flowchart illustrating an example of omitting a recovery operation according to a reception condition of a second read command of FIG. 1.

Referring to FIGS. 1 and 2, when omitting the recovery operation according to the reception condition of the second read command (operation S300), it may be determined whether the second read command is received within the reference time interval (operation S311). For example, the reference time interval may be predetermined depending on operation characteristics of the nonvolatile memory device at the design phase and/or the manufacture phase.

When the second read command is received within the reference time interval (operation S311: YES), it may be determined that the recovery operation is unnecessary to reduce the amount of time used for the read operation and a latency of the read operation in a sequential read operation. Accordingly, the recovery operation may be omitted (operation S313). Thereafter, the second sensing operation may be performed immediately based on the second read command in operation S400 since the second read command has been received.

The nonvolatile memory device may determine that that the reference time interval has elapsed without receiving the second read command. In response to determining that the second read command is not received after the reference time interval elapses (operation S311: NO), the nonvolatile memory device determines to perform the recovery operation to reduce the power consumption when reception of a next command is excessively delayed even in the sequential read operation. Accordingly, the recovery operation may be performed (operation S315). Since the second read command has not been received yet, thereafter, the second sensing operation may be performed based on the reception of the second read command when the second read command is received while pending the reception of the second read command in operation S400.

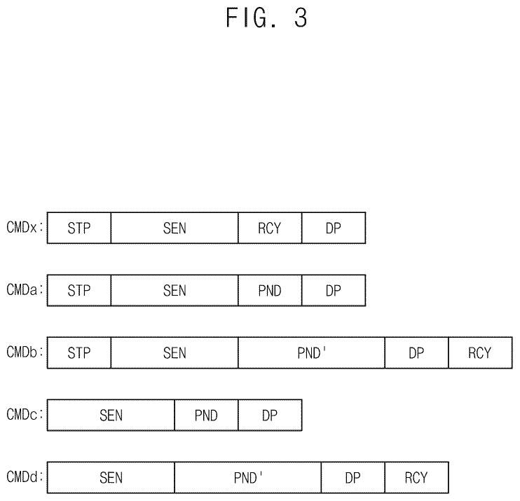

FIG. 3 is a diagram for describing an example of a method of reading data from a nonvolatile memory device.

Referring to FIG. 3, examples of various operations performed based on read commands CMDx, CMDa, CMDb, CMDc and CMDd are illustrated.

Conventionally, when the read command CMDx is received and the read operation is performed based on the read command CMDx, the entire time interval of performing the read operation may include a setup time interval STP, a sensing time interval SEN, a recovery time interval RCY and a dump time interval DP.

For example, in the setup time interval STP, a prepulse may be applied to string selection lines, and a wordline voltage may be applied to the selected wordline and the unselected wordlines. For example, in the sensing time interval SEN, voltages of bitlines precharged to a predetermined voltage level may be developed according to data stored in the memory cell. For example, in the recovery time interval RCY, the recovery operation associated with the wordline and/or bitlines may be performed. For example, in the dump time interval DP, the data read by the sensing operation and stored in a page buffer may be transmitted to an input/output (I/O) buffer. In some implementations, the order of the recovery time interval RCY and the dump time interval DP may be changed.

When the read command CMDa is received and the read operation is performed based on the read command CMDa, and when a next read command is received within the reference time interval (e.g., operation S311 in FIG. 2: YES), the recovery operation may be omitted. For example, a pending time interval PDN of pending reception of the next read command may be disposed after the setup time interval STP and the sensing time interval SEN. When the pending time interval PDN is shorter than or equal to the reference time interval, the recovery time interval RCY and the recovery operation may be omitted, and the dump time interval DP may be performed.

When the read command CMDb is received and the read operation is performed based on the reception, and the next read command is not received after the reference time interval elapses (e.g., operation S311 in FIG. 2: NO), the recovery operation may be performed. For example, a pending time interval PDN′ of pending the reception of the next read command may be disposed after the setup time interval STP and the sensing time interval SEN. When the pending time interval PDN′ is longer than the reference time interval, the dump time interval DP may be performed, and thereafter, the recovery time interval RCY and the recovery operation may be performed

The read operations in response to the read command CMDc and the read command CMDd may be substantially the same as the read operations in response to the read command CMDa and the read command CMDb, respectively, except that the setup time interval STP is omitted. For example, when the read operations associated with the same memory cell connected to the same wordline and the same string selection line are performed sequentially, or when the read operations associated with different memory cells connected to different wordlines and the same string selection line are performed sequentially, the setup time interval STP may be omitted.

In the method of reading data from a nonvolatile memory device, while pending the reception of the next command in the sequential read operations, the voltage of the selected wordline and the voltages of the unselected wordlines may be controlled such that the voltage of the selected wordline and the voltages of the unselected wordlines have the same voltage level, and the recovery operation may be omitted selectively. Accordingly, the amount of time used for the read operation and the latency of the read operation may be reduced, and the read operation may be performed efficiently because the recovery operation does not need to be performed each time the read operation is performed. In addition, the power consumption of the nonvolatile memory device may be reduced by decreasing the voltage levels of the wordlines and omitting the recovery operation.

FIG. 4 is a block diagram illustrating an example of a nonvolatile memory device.

Referring to FIG. 4, a nonvolatile memory device 500 includes a memory cell array 510, a voltage generator 550 and a control circuit 560. The nonvolatile memory device 500 may further include an address decoder 520, a page buffer circuit 530 and a data input/output (I/O) circuit 540.

The memory cell array 510 is connected to a plurality of string selection lines SSL, a plurality of wordlines WL and a plurality of ground selection lines GSL through the address decoder 520. In addition, the memory cell array 510 is connected to the page buffer circuit 530 through a plurality of bitlines BL. The memory cell array 510 may include the plurality of memory cells connected to the plurality of wordlines WL and the plurality of bitlines BL. The memory cell array 510 may be divided into a plurality of memory blocks BLK1, BLK2, . . . , BLKz each of which includes memory cells. In addition, each of memory blocks BLK1, BLK2, . . . , BLKz may be divided into a plurality of pages.

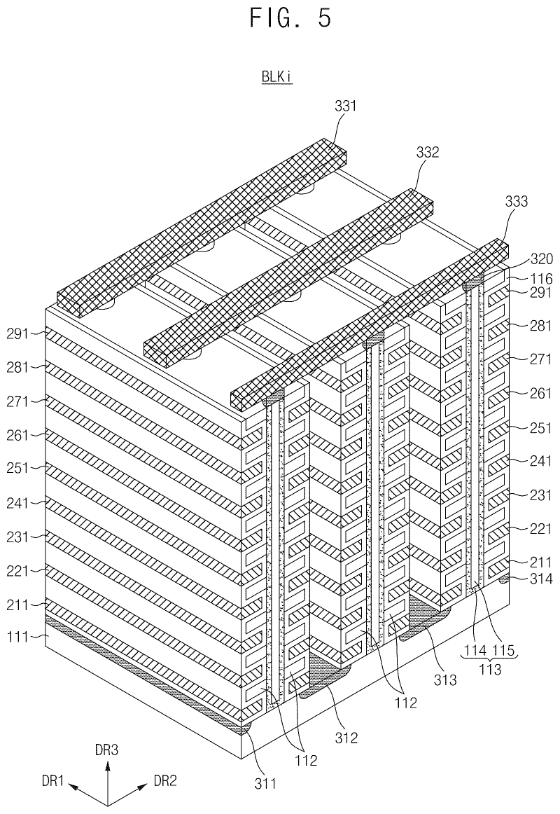

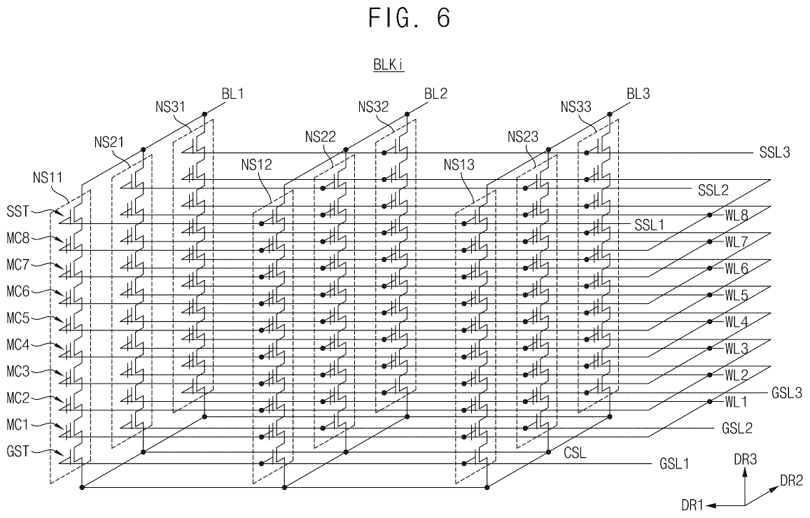

In some implementations, the memory cell array 510 may be a three-dimensional (3D) memory cell array disposed on the substrate in a three dimensional structure (or a vertical structure) as will be described with reference to FIGS. 5 and 6. For example, the memory cell array 510 may include cell strings (e.g., vertical memory NAND strings) including the plurality of memory cells formed by stacking each other.

The control circuit 560 may receive a command CMD and an address ADDR from an outside (e.g., from a memory controller 20 in FIG. 17), and may control program loops, erasure loops and read operations of the nonvolatile memory device 500 based on the command CMD and the address ADDR.

For example, the control circuit 560 may generate control signals CON, which are used for controlling the voltage generator 550, and may generate a control signal PBC for controlling the page buffer circuit 530, based on the command CMD, and may generate a row address R_ADDR and a column address C_ADDR based on the address ADDR. The control circuit 560 may provide the row address R_ADDR to the address decoder 520 and may provide the column address C_ADDR to the data I/O circuit 540.

The control circuit 560 may control the address decoder 520, the page buffer circuit 530, the data I/O circuit 540 and the voltage generator 550 to perform the method of reading data described with reference to FIGS. 1 and 2. For example, while pending the reception of the next read command, the control circuit 560 may control voltages of the plurality of wordlines WL and omit the recovery operation according to the reception condition of the next read command. For example, the control circuit 560 may include a recovery controller 562 for performing the operations described above.

The address decoder 520 is connected to the memory cell array 510 via the plurality of string selection lines SSL, the plurality of wordlines WL and the plurality of ground selection lines GSL. For example, in the erase/write/read operations, the address decoder 520 may determine at least one of the plurality of wordlines WL as a selected wordline, may determine at least one of the plurality of string selection lines SSL as a selected string selection line, and may determine at least one of the plurality of ground selection lines GSL as a selected ground selection line, based on the row address R_ADDR.

The voltage generator 550 generates voltages VS that are required for an operation of the nonvolatile memory device 500 based on a power PWR and the control signals CON. The voltages VS may be applied to the plurality of string selection lines SSL, the plurality of wordlines WL and the plurality of ground selection lines GSL via the address decoder 520. For example, the control signals CON may include the signals to control the voltages of the plurality of wordlines WL. In addition, the voltage generator 550 may generate an erase voltage VERS that is required for the erase operation based on the power PWR and the control signals CON.

The page buffer circuit 530 may be connected to the memory cell array 510 via the plurality of bitlines BL. The page buffer circuit 530 may include a plurality of page buffers. The page buffer circuit 530 may store data DAT to be programmed into the memory cell array 510 or may read data DAT sensed from the memory cell array 510. In other words, the page buffer circuit 530 may operate as a write driver or a sensing amplifier depending on an operation mode of the nonvolatile memory device 500.

The data I/O circuit 540 may be connected to the page buffer circuit 530 via data lines DL. The data I/O circuit 540 may provide the data DAT to the memory cell array 510 via the page buffer circuit 530 or may provide the data DAT from the memory cell array 510 to the outside of the nonvolatile memory 500, based on the column address C_ADDR.

FIG. 5 is a perspective view of an example of a memory block included in a memory cell array in a nonvolatile memory device of FIG. 4.

Referring to FIG. 5, a memory block BLKi may include a plurality of cell strings (e.g., a plurality of vertical NAND strings) which may be formed on a substrate in a 3D structure (or a vertical structure). The memory block BLKi may include structures extending along a first direction DR1, a second direction DR2, and/or a third direction DR3. Two directions may be substantially parallel to a first surface (e.g., a top surface) of a substrate 111 and may cross each other, and may be respectively referred to as the first direction DR1 (e.g., a X-axis direction) and the second direction DR2 (e.g., a Y-axis direction). In addition, a direction substantially vertical to the first surface of the substrate 111 may be referred to as the third direction DR3 (e.g., a Z-axis direction). For example, the first and second directions DR1 and DR2 may be substantially perpendicular to each other. In addition, the third direction DR3 may be substantially perpendicular to both the first and second directions DR1 and DR2. The first direction DR1, the second direction DR2, and the third direction DR3 may each refer to the X-axis direction, Y-axis direction, and Z-axis direction, respectively.

The substrate 111 may have a well of a first type of charge carrier impurity (e.g., a first conductivity type) therein. For example, the substrate 111 may have a p-well formed by implanting a Group III element such as, but not limited to, boron (B). As another example, the substrate 111 may have a pocket p-well provided within an n-well. In some implementations, the substrate 111 may have a p-type well (or a p-type pocket well). However, the conductive type of the substrate 111 is not limited to p-type.

A plurality of doping regions (e.g., a first doping region 311, a second doping region 312, a third doping region 313, and a fourth doping region 314) that may be arranged along the second direction DR2 may be provided in and/or on the substrate 111. The plurality of doping regions 311 to 314 may have a second type of charge carrier impurity (e.g., a second conductivity type) different from the first type of the substrate 111. In some implementations, the first to fourth doping regions 311 to 314 may be an n-type. However, the conductive type of the first to fourth doping regions 311 to 314 is not limited to n-type.

A plurality of insulation materials 112 extending along the first direction DR1 may be sequentially provided along the third direction DR3 on a region of the substrate 111 between the first and second doping regions 311 and 312. For example, the plurality of insulation materials 112 may be provided along the third direction DR3, being spaced by a specific distance. The insulation materials 112 may include an insulation material such as, but not limited to, an oxide layer.

A plurality of pillars 113 penetrating the insulation materials along the third direction DR3 may be sequentially disposed along the first direction DR1 on a region of the substrate 111 between the first and second doping regions 311 and 312. For example, the plurality of pillars 113 may at least partially penetrate the insulation materials 112 to contact the substrate 111.

In some implementations, each pillar of the plurality of pillars 113 may include a plurality of materials. For example, a channel layer 114 of each pillar 113 may include a silicon material having a first conductivity type. As another example, the channel layer 114 of each pillar of the plurality of pillars 113 may include a silicon material having the same conductivity type as the substrate 111. In some implementations, the channel layer 114 of each pillar of the plurality of pillars 113 may include, but not be limited to, p-type silicon. However, the channel layer 114 of each pillar of the plurality of pillars 113 is not limited to the p-type silicon.

An internal material 115 of each pillar of the plurality of pillars 113 may include an insulation material. For example, the internal material 115 of each pillar of the plurality of pillars 113 may include an insulation material such as, but not be limited to, a silicon oxide. In an example, the internal material 115 of each pillar 113 may include an air gap. As used herein, the term air may refer to atmospheric air and/or other gases that may be present during the manufacturing process.

An insulation layer 116 may be provided along the exposed surfaces of the insulation materials 112, the plurality of pillars 113, and the substrate 111, on a region between the first and second doping regions 311 and 312. For example, the insulation layer 116 provided on surfaces of the insulation material 112 may be interposed between the plurality of pillars 113 and a plurality of stacked first conductive materials (e.g., a first conductive material 211, a second conductive material 221, a third conductive material 231, a fourth conductive material 241, a fifth conductive material 251, a sixth conductive material 261, a seventh conductive material 271, an eighth conductive material 281, and a ninth conductive material 291), as shown in FIG. 5. In some implementations, the insulation layer 116 may not be provided between the first conductive materials 211 to 291 corresponding to ground selection lines GSL (e.g., first conductive material 211) and string selection lines SSL (e.g., ninth conductive material 291). In such implementations, the ground selection lines GSL may be the lowermost ones of the stack of first conductive materials 211 to 291 and the string selection lines SSL may be the uppermost ones of the stack of first conductive materials 211 to 291.

The plurality of first conductive materials 211 to 291 may be provided on surfaces of the insulation layer 116, in a region between the first and second doping regions 311 and 312. For example, the first conductive material 211 extending along the first direction DR1 may be provided between the insulation material 112 adjacent to the substrate 111 and the substrate 111. That is, the first conductive material 211 extending along the first direction DR1 may be provided between the insulation layer 116 at the bottom of the insulation material 112 adjacent to the substrate 111 and the substrate 111.

A first conductive material extending along the first direction DR1 may be provided between the insulation layer 116 at the top of the specific insulation material from among the insulation materials 112 and the insulation layer 116 at the bottom of a specific insulation material from among the insulation materials 112. For example, a plurality of first conductive materials 221 to 281 extending along the first direction DR1 may be provided between the insulation materials 112. The insulation layer 116 may be provided between the insulation materials 112 and the first conductive materials 221 to 281. The plurality of stacked first conductive materials 211 to 291 may be formed of a conductive metal. However, the present disclosure is not limited in this regard, and the plurality of stacked first conductive materials 211 to 291 may include a conductive material such as, but not limited to, a polysilicon in other implementations.

The same and/or substantially similar structures as those on the first and second doping regions 311 and 312 may be provided in a region between the second and third doping regions 312 and 313. In the region between the second and third doping regions 312 and 313, a plurality of insulation materials 112 may be provided, which may extend along the first direction DR1. A plurality of pillars 113 may be provided that may be disposed sequentially along the first direction DR1 and at least partially penetrate the plurality of insulation materials 112 along the third direction DR3. An insulation layer 116 may be provided on the exposed surfaces of the plurality of insulation materials 112 and the plurality of pillars 113, and the plurality of stacked first conductive materials 211 to 291 may extend along the first direction DR1. Similarly, the same and/or substantially similar structures as those on the first and second doping regions 311 and 312 may be provided in a region between the third and fourth doping regions 313 and 314.

A plurality of drain regions 320 may be provided on the plurality of pillars 113, respectively. The drain regions 320 may include, but not be limited to, silicon materials doped with a second type of charge carrier impurity. For example, the drain regions 320 may include silicon materials doped with an n-type dopant. In some implementations, the drain regions 320 may include n-type silicon materials. However, the drain regions 320 are not limited to n-type silicon materials.

On the drain regions, a plurality of second conductive materials (e.g., a tenth conductive material 331, an eleventh conductive material 332, and a twelfth conductive material 333) may be provided, which may extend along the second direction DR2. The second conductive materials 331 to 333 may be disposed along the first direction DR1, being spaced apart from each other by a specific distance. The second conductive materials 331 to 333 may be respectively connected to the drain regions 320 in a corresponding region. The drain regions 320 and the twelfth conductive material 333 extending along the second direction DR2 may be connected through each contact plug. Each contact plug may be, for example, a conductive plug formed of a conductive material such as, but not limited to, a metal. The second conductive materials 331 to 333 may include metal materials. The second conductive materials 331 to 333 may include conductive materials such as, but not limited to, a polysilicon.

As illustrated in FIG. 5, the stacked first conductive materials 211 to 291 may be used to form the wordlines WL, the string selection lines SSL, and the ground selection lines GSL. For example, the stacked first conductive materials 221 to 281 may be used to form the wordlines WL, where conductive materials belonging to the same layer may be interconnected. The second conductive materials 331 to 333 may be used to form the bitlines BL. The number of layers of the stacked first conductive materials 211 to 291 may be variously determined according to process and control techniques.

In an example of FIG. 5, the first conductive materials 211 to 291 may form the wordlines WL, the string selection lines SSL and the ground selection lines GSL. The second conductive materials 331 to 333 may form the bitlines BL.

FIG. 6 is a circuit diagram illustrating an equivalent circuit of a memory block described with reference to FIG. 5.

A memory block BLKi of FIG. 6 may be formed on a substrate in a 3D structure (or a vertical structure). For example, a plurality of cell strings included in the memory block BLKi may be formed in a direction perpendicular to the substrate.

Referring to FIG. 6, the memory block BLKi includes a plurality of cell strings (e.g., a first cell string NS11, a second cell string NS12, a third cell string NS13, a fourth cell string NS21, a fifth cell string NS22, a sixth cell string NS23, a seventh cell string NS31, an eighth cell string NS32, and a ninth cell string NS33) that may be connected (e.g., communicatively coupled) between bitlines (e.g., a first bitline BL1, a second bitline BL2, and a third bitline BL3) and a common source line CSL. Each of the cell strings NS11 to NS33 may include a string selection transistor SST, a plurality of memory cells (e.g., a first memory cell MC1, a second memory cell MC2, a third memory cell MC3, a fourth memory cell MC4, a fifth memory cell MC5, a sixth memory cell MC6, a seventh memory cell MC7, and an eighth memory cell MC8), and a ground selection transistor GST. For example, the bitlines BL1 to BL3 may correspond to the second conductive materials 331 to 333 in FIG. 5, and the common source line CSL may be formed by interconnecting the first to fourth doping regions 311 to 314 in FIG. 5.

Each string selection transistor SST may be connected to a corresponding string selection line (e.g., one of a first string selection line SSL1, a second string selection line SSL2, and a third string selection line SSL3). The plurality of memory cells MC1 to MC8 may be connected (e.g., communicatively coupled) to corresponding wordlines (e.g., at least one of a first wordline WL1, a second wordline WL2, a third wordline WL3, a fourth wordline WL4, a fifth wordline WL5, a sixth wordline WL6, a seventh wordline WL7, and an eighth wordline WL8), respectively. Each ground selection transistor GST may be connected to a corresponding ground selection line (e.g., one of a first ground selection line GSL1, a second ground selection line GSL2, and a third ground selection line GSL3). Each string selection transistor SST may be connected to a corresponding bitline (e.g., one of first to third bitlines BL1 to BL3), and each ground selection transistor GST may be connected to the common source line CSL.

The cell strings connected in common to one bitline may form one column, and the cell strings connected to one string selection line may form one row. For example, the first, fourth, and seventh cell strings NS11, NS21 and NS31 connected to the first bitline BL1 may correspond to a first column, and the cell strings first, second, and third NS11, NS12 and NS13 connected to the first string selection line SSL1 may form a first row.

The following patent documents, which are hereby incorporated by reference in their entireties, describe configurations for a memory cell array including a 3D vertical array structure, in which the three-dimensional memory array is configured as a plurality of levels, with wordlines and/or bitlines shared between levels: U.S. Pat. Nos. 7,679,133; 8,553,466; 8,654,587; 8,559,235; and U.S. Pat. Pub. No. 2011/0233648.

Although the memory cell array is described based on a vertical memory cell array, the memory cell array may be any memory cell array, e.g., a planar (or two-dimensional) memory cell array. Although the nonvolatile memory device is described based on a NAND flash memory device, the nonvolatile memory device, may be and/or may include other types of nonvolatile memory devices, such as, but not limited to, phase-change random access memory (PRAM) devices, resistive random access memory (RRAM) devices, nano floating gate memory (NFGM) devices, polymer random access memory (PoRAM) devices, magnetic random access memory (MRAM) devices, a ferroelectric random access memory (FRAM), thyristor random access memory (TRAM) devices, and the like.

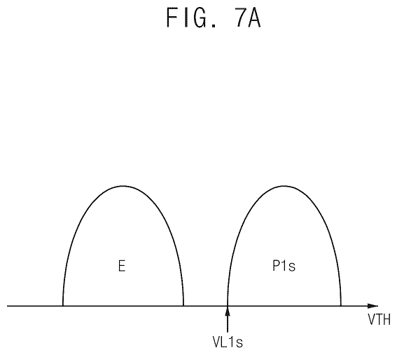

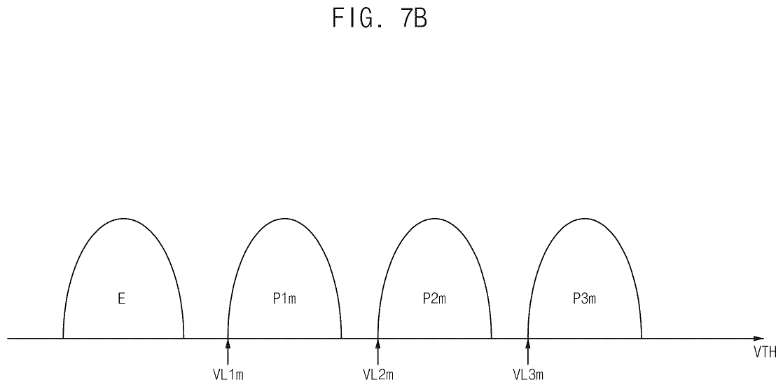

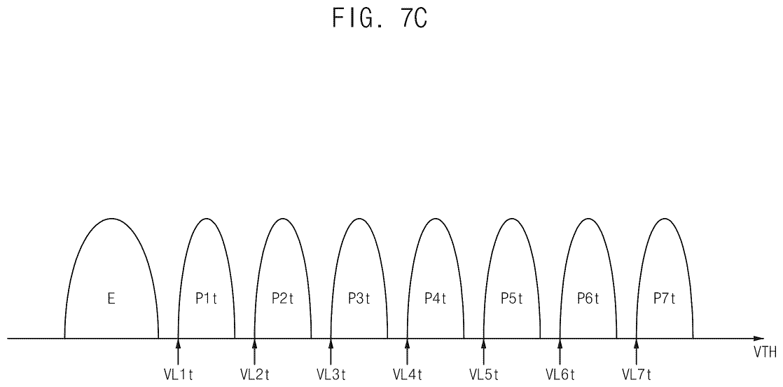

FIGS. 7A, 7B and 7C are diagrams for describing an example of a threshold voltage distribution of data stored in a nonvolatile memory device.

Referring to FIG. 7A, an example where each of the plurality of memory cells included in the memory cell array stores one data bit, e.g., an example where each memory cell is a single-level memory cell (SLC) storing 1-bit data is illustrated. Each of SLCs may have one of an erase state E and a program state Pls, and a threshold voltage distribution of the SLCs may include the states E and Pls. A voltage level VLIs may be used to distinguish or determine the states E and Pls.

Referring to FIG. 7B, an example where each of the plurality of memory cells stores two data bits, e.g., an example where each memory cell is a multi-level memory cell (MLC) storing 2-bit data is illustrated. Each of MLCs may have one of an erase state E and a plurality of program states P1m, P2m and P3m, and a threshold voltage distribution of the MLCs may include the states E and P1m to P3m. Voltage levels VL1m, VL2m and VL3m may be used to distinguish or determine the states E and P1m to P3m. For example, it may be distinguished using the voltage level VL1m whether each MLC has the erase state E or the program state P1m.

Referring to FIG. 7C, an example where each of the plurality of memory cells stores three data bits, e.g., an example where each memory cell is a triple-level memory cell (TLC) storing 3-bit data, is illustrated. Each of TLCs may have one of an erase state E and a plurality of program states P1t, P2t, P3t, P4t, P5t, P6t and P7t, and a threshold voltage distribution of the TLCs may include the states E and P1t to P7t. Voltage levels VLIt, VL2t, VL3t, VL4t, VL5t, VL6t and VL7t may be used to distinguish or determine the states E and P1t to P7t.

In some implementations, when the memory cells have at least two program states (e.g., when each memory cell stores two or more data bits) as illustrated in FIGS. 7B and 7C, the memory cells may be programmed based on a one-shot scheme in which the program states are formed at once. In some implementations, when the memory cells have at least two program states as illustrated in FIGS. 7B and 7C, the memory cells may be programmed based on a multi-step scheme in which the program states are formed by a plurality of steps.

Although examples are described based on the MLCs and the TLCs, example implementations are not limited thereto, and each memory cell may be an arbitrary multi-bit cell that stores k-bit data and is programmed such that each memory cell has one of 2^{k} states, where k is a positive integer greater than or equal to two.

FIG. 8 is a flowchart illustrating an example of controlling voltages of a plurality of wordlines of FIG. 1.

Referring to FIGS. 1 and 8, when controlling the voltages of the plurality of wordlines (operation S200), the voltage levels of the voltages of the unselected wordlines may decrease from a first voltage level to a second voltage level (operation S210), and the voltage level of the voltage of the selected wordline may increase from a third voltage level to the second voltage level (operation S220). In other words, the voltages of the unselected wordlines and the voltage of the selected wordline may be controlled such that the selected and unselected wordlines all have the second voltage level.

In some implementations, the second voltage level may be higher than an initial voltage level of the voltage of the selected wordline at a beginning of the second sensing operation. In some implementations, the second voltage level may be lower than the initial voltage level of the voltage of the selected wordline at the beginning of the second sensing operation.

FIGS. 9A, 9B, 10A, 10B, 11A, 11B, 12, 13A, 13B, 13C, 14A and 14B are diagrams for describing an example of a method of reading data from a nonvolatile memory device. Hereinafter, examples will be described based on that each memory cell is the TLC storing the 3-bit data. However, example implementations are not limited thereto.

Referring to FIG. 9A, an example of performing the sequential read operations based on commands CMD1, CMD2 and CMD3 associated with the same TLC connected to the same wordline and the same string selection line is illustrated. RnBx and RnBi may represent an external ready/busy signal and an internal ready/busy signal, respectively, each of which represents the operation state of the nonvolatile memory device.

For example, the first command CMD1 may be a command to read a least significant bit (LSB) among the data stored in the TLC.

When the first read command CMD1 and a first read address ADDR_LSB corresponding to the first read command CMD1 are received, a first setup time interval STP1, a first sensing time interval SEN1, a first pending time interval PND1 and a first dump time interval DP1 may be performed sequentially.

A voltage of a selected string selection line V_SEL_SSL and voltages of unselected string selection lines V_UNSEL_SSL may be controlled as illustrated in FIG. 9A, based on the first read command CMD1 and the first read address ADDR_LSB corresponding thereto. In FIG. 9A and the following figures, the voltage of the selected string selection line V_SEL_SSL is shown as a solid line, and the voltages of the unselected string selection lines V_UNSEL_SSL are shown as a dotted line.

In the first setup time interval STP1, the voltage of the selected string selection line V_SEL_SSL and the voltages of the unselected string selection lines V_UNSEL_SSL may increase by providing the prepulse. Thereafter, in the first sensing time interval SEN1, the first pending time interval PND1, and the first dump time interval DP1, the voltage of the selected string selection line V_SEL_SSL may maintain the increased voltage level, and the voltages of the unselected string selection lines V_UNSEL_SSL may decrease and be maintained at a low voltage level.

A voltage of a selected wordline V_SEL_WL and voltages of unselected wordlines V_UNSEL_WL may be controlled as illustrated in FIG. 9A, based on the first read command CMD1 and the first read address ADDR_LSB corresponding thereto. In FIG. 9A and the following figures, the voltage of the selected wordline V_SEL_WL is shown with a solid line, and the voltages of the unselected wordlines V_UNSEL_WL are shown with a dotted line.

In the first setup time interval STP1, the voltage of the selected wordline V_SEL_WL and the voltages of the unselected wordlines V_UNSEL_WL may increase by providing the wordline voltage. Thereafter, in the first sensing time interval SEN1, the voltages of the unselected wordlines V_UNSEL_WL may maintain an increased voltage level L0, and the voltage of the selected wordline V_SEL_WL may be sequentially changed to voltage levels RD5 and RD1 to sense the LSB. For example, the voltage levels RD5 and RD1 may correspond to the voltage levels VL5t and VLIt of FIG. 7C, respectively. Thereafter, in the first pending time interval PND1, the voltages of the unselected wordlines V_UNSEL_WL may decrease, and the voltage of the selected wordline V_SEL_WL may increase, such that all voltages may have a voltage level L1. For example, the voltages of the unselected wordlines V_UNSEL_WL may decrease from the voltage level L0 to the voltage level L1, and the voltage of the selected wordline V_SEL_WL may increase from the voltage level RD1 to the voltage level L1. Thereafter, in the first dump time interval DP1, the voltages of the unselected wordlines V_UNSEL_WL may increase, and the voltage of the selected wordline V_SEL_WL may decrease. Although not shown, in some implementations, the voltages of wordlines adjacent to the selected wordline, that is, when the selected wordline is a wordline WLm, voltages of wordlines WLm+1 and WLm−1 may maintain a voltage level higher than the voltage level L0 in the first sensing time interval SEN1.

For example, the second read command CMD2 may be a command for reading the central significant bit (CSB) among the data stored in the TLC. In the example of FIG. 9A, the second read command CMD2 is received within the reference time interval in the first pending time interval PND1, and therefore the recovery time interval and the recovery operation may be omitted.

When the second read command CMD2 and a second read address ADDR_CSB corresponding to the second read command CMD2 are received, a second sensing time interval SEN2, a second pending time interval PND2 and a second dump time interval DP2 may be sequentially performed. An operation corresponding to a second setup time interval may not be performed since this operation is the sequential read operation in response to the same TLC, that is, because the selected string selection line has not been changed.

Since the setup time interval is not performed based on the second read command CMD2 and the second read address ADDR_CSB corresponding thereto, the voltage of the selected string selection line V_SEL_SSL and the voltages of the unselected string selection lines V_UNSEL_SSL may be maintained without change.

Based on the second read command CMD2 and the second read address ADDR_CSB corresponding thereto, the voltage of the selected wordline V_SEL_WL and the voltages of the unselected wordlines V_SEL_WL may be controlled as illustrated in FIG. 9A.

In the second sensing time interval SEN2, the voltages of the unselected wordlines V_UNSEL_WL may maintain the increased voltage level L0, and the voltage of the selected wordline V_SEL_WL may be sequentially changed to voltage levels RD6, RD4 and RD2 for sensing the CSB. For example, the voltage levels RD6, RD4 and RD2 may correspond to the voltage levels VL6t, VL4t and VL2t of FIG. 7C, respectively. Thereafter, in the second pending time interval PND2, the voltages of the unselected wordlines V_UNSEL_WL may decrease, and the voltage of the selected wordline V_SEL_WL may increase such that all voltages may have the voltage level L1. For example, the voltages of the unselected wordlines V_UNSEL_WL may decrease from the voltage level L0 to the voltage level L1, and the voltage of the selected wordline V_SEL_WL may increase from the voltage level RD2 to the voltage level L1. Thereafter, in the second dump time interval DP2, the voltages of the unselected wordlines V_UNSEL_WL may increase, and the voltage of the selected wordline V_SEL_WL may decrease.

For example, the third read command CMD3 may be a command for reading the most significant bit (MSB) among the data stored in the TLC. In the example of FIG. 9A, the third read command CMD3 is received within the reference time interval in the second pending time interval PND2, and therefore the recovery time interval and the recovery operation may be omitted.

When the third read command CMD3 and a third read address ADDR_MSB corresponding to the third read command CMD3 are received, a third sensing time interval SEN3 and a third pending time interval PND3 may be sequentially performed, and a third dump time interval (e.g., the dump time interval DP3 of FIG. 12) may also be performed. Since the operation is the sequential read operation associated with the same TLC, a third setup time interval is not performed similarly to the example of the second read command CMD2, and the voltage of the selected string selection line V_SEL_SSL and the voltages of the unselected string selection lines V_UNSEL_SSL may be maintained without change.

Based on the third read command CMD3 and the third read address ADDR_MSB corresponding to the third read command CMD3, the voltage of the selected wordline V_SEL_WL and the voltages of the unselected wordlines V_UNSEL_WL may be controlled as illustrated in FIG. 9A.

In the third sensing time interval SEN3, the voltages of the unselected wordlines V_UNSEL_WL may maintain the increased voltage level L0, and the voltage of the selected wordline V_SEL_WL may be sequentially changed to voltage levels RD7 and RD3 for sensing the MSB. For example, the voltage levels RD7 and RD3 may correspond to the voltage levels VL7t and VL3t of FIG. 7C, respectively. Thereafter, in the third pending time interval PND3, the voltages of the unselected wordlines V_UNSEL_WL may decrease, and the voltage of the selected wordline V_SEL_WL may increase such that all voltages may have the voltage level L1. For example, the voltages of the unselected wordlines V_UNSEL_WL may decrease from the voltage level L0 to the voltage level L1, and the voltage of the selected wordline V_SEL_WL may increase from the voltage level RD3 to the voltage level L1.

In some implementations, the voltage level L1 of the voltage of the selected wordline V_SEL_WL and the voltages of the unselected wordlines V_UNSEL_WL in the first pending time interval PND1 may be set to be higher than the initial voltage level RD6 of the voltage of the selected wordline V_SEL_WL at the beginning of the operation in the subsequent second sensing time interval SEN2. Similarly, in the second pending time interval PND2, the voltage level L1 of the voltage of the selected wordline V_SEL_WL and the voltages of the unselected wordlines V_SEL_WL may be set to be higher than the initial voltage level RD7 of the voltage of the selected wordline V_SEL_WL at the beginning of the operation in the subsequent third sensing time interval SEN3.

Although examples are described that the voltage level L1 in the first pending time interval PND1 and the voltage level L1 in the second pending time interval PND2 are the same, example implementations are not limited thereto. For example, the voltage level in the first pending time interval PND1 may be different from the voltage level in the second pending time interval PND2.

In some implementations, a predetermined time interval for the first pending time interval PND1 and the second pending time interval PND2 may be associated with the time interval for the voltage of the selected wordline V_SEL_WL and the voltages of the unselected wordlines V_UNSEL_WL to reach and maintain the voltage level L1 stably, e.g., to stabilize. For example, in the first pending time interval PND1, the predetermined time interval may include the time interval for the voltages of the unselected wordlines V_UNSEL_WL to decrease from the voltage level L0 to the voltage level L1 and stabilize and the time interval for the voltage of the selected wordline V_SEL_WL to increase from the voltage level RD3 to the voltage level L1 and stabilize.

Referring to FIG. 9B, the operation may be substantially the same as described with reference to FIG. 9A except for the difference in the voltage level L1 in the first pending time interval PND1 and the second pending time interval PND2. The descriptions repeated with or overlapping with descriptions of FIG. 9A will be omitted in the interest of brevity.

In some implementations, a voltage level L2 of the selected wordline V_SEL_WL and the voltages of the unselected wordlines V_UNSEL_WL in the first pending time interval PND1 may be set to be lower than the initial voltage level RD6 of the selected wordline V_SEL_WL at the beginning of the operation in the subsequent second sensing time interval SEN2, and thus the voltage of the selected wordline V_SEL_WL may increase in the first dump time interval DP1. Similarly, in the second pending time interval PND2, the voltage level L1 of the selected wordline V_SEL_WL and the voltages of the unselected wordlines V_UNSEL_WL may be set to be lower than the initial voltage level RD7 of the selected wordline V_SEL_WL at the beginning of the operation in the subsequent third sensing time interval SEN3, and thus the voltage of the selected wordline V_SEL_WL may increase in the second dump time interval DP2.

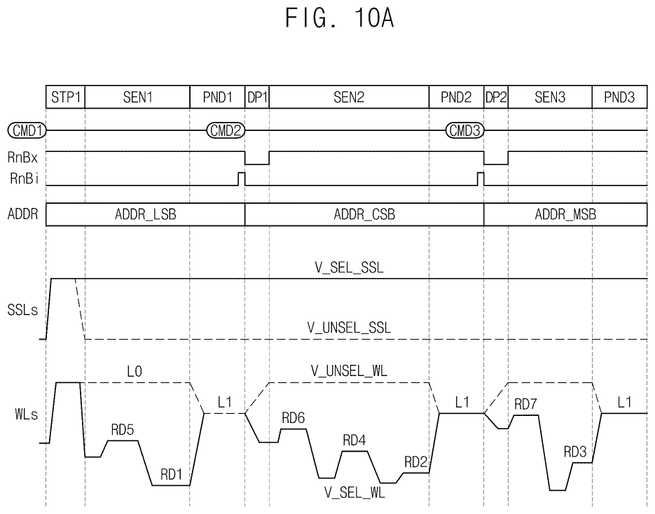

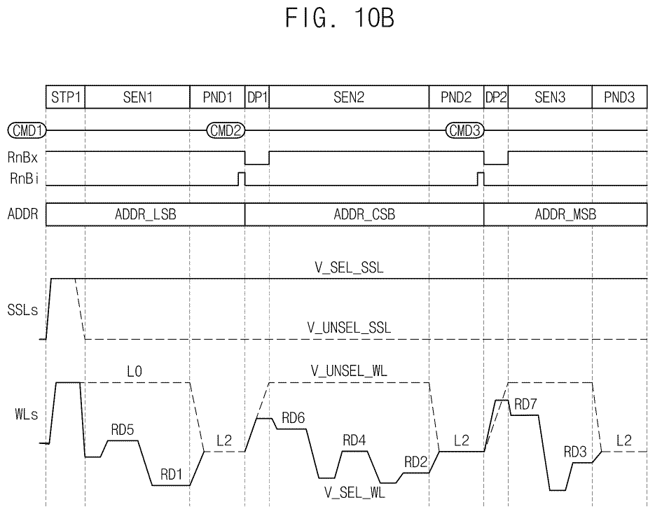

Referring to FIG. 10A, the operation may be substantially the same as described with reference to FIG. 9A except for the difference in the change of the voltage of the selected wordline V_SEL_WL in the first dump time interval DP1 and the second dump time interval DP2. The descriptions repeated with or overlapping with descriptions of FIG. 9A will be omitted in the interest of brevity.

In the first dump time interval DP1, instead of the voltage of the selected wordline V_SEL_WL directly decreasing from the voltage level L1 to the voltage level RD6, the voltage of the selected wordline V_SEL_WL may decrease to a voltage level lower than the voltage level RD6 and then increase to the voltage level RD6. Similarly, in the second dump time interval DP2, instead of the voltage of the selected wordline V_SEL_WL directly decreasing from the voltage level L1 to the voltage level RD7, the voltage of the selected wordline V_SEL_WL may decrease to a voltage level lower than the voltage level RD7 and then increase to the voltage level RD7.

Referring to FIG. 10B, the operation may be substantially the same as described with reference to FIG. 9B except for the difference in the change in the voltage of the selected wordline V_SEL_WL in the first dump time intervals DP1 and the second dump time intervals DP2. The descriptions repeated with or overlapping with descriptions of FIG. 9A and FIG. 9B will be omitted in the interest of brevity.

In the first dump time interval DP1, instead of the voltage of the selected wordline V_SEL_WL directly increasing from the voltage level L1 to the voltage level RD6, the selected wordline V_SEL_WL may first increase to a voltage level higher than the voltage level RD6 and then decrease to the voltage level RD6. Similarly, in the second dump time interval DP2, instead of the voltage of the selected wordline V_SEL_WL directly increasing from the voltage level L1 to the voltage level RD7, the selected wordline V_SEL_WL may first increase to a voltage level higher than the voltage level RD7 and then decrease to the voltage level RD7.

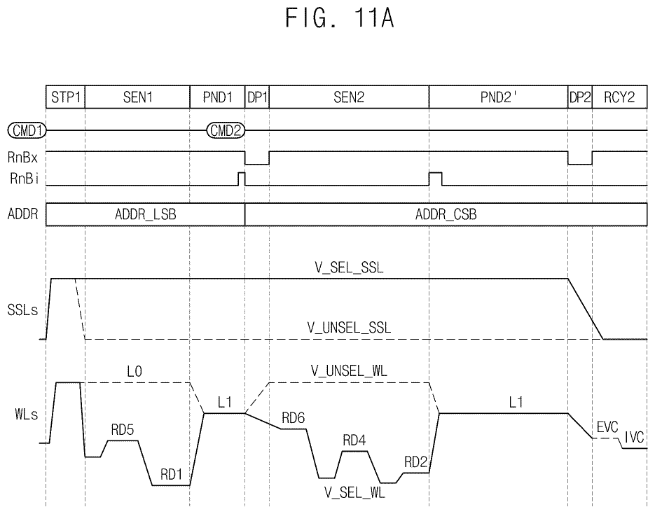

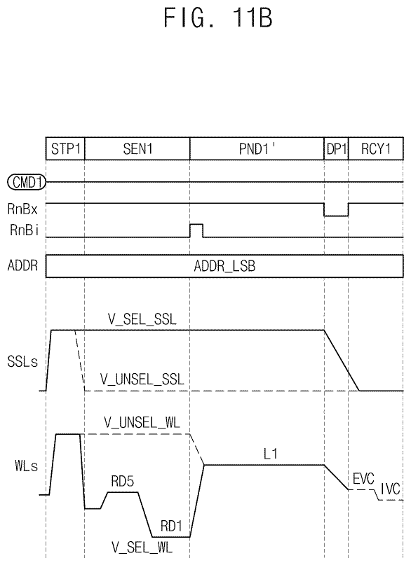

Referring to FIG. 11A, an example where the third read command CMD3 is not received after the reference time interval elapses in a second pending time interval PND2′ is illustrated, as compared to FIG. 9A. The descriptions repeated with or overlapping with descriptions of FIG. 9A will be omitted for brevity.

Since the third read command CMD3 has not been received, the operations corresponding to the third sensing time interval SEN3, third pending time interval PND3 and the third dump time interval DP3 may not be performed after the second dump time interval DP2. Instead, an operation corresponding to a second recovery time interval RCY2 may be performed after the second dump time interval DP2. Since the recovery operation is performed in the second recovery time interval RCY2, the voltage of the selected string selection line V_SEL_SSL may decrease to the same voltage level as the voltages of the unselected string selection lines V_UNSEL_SSL, and the voltage of the selected wordline V_SEL_WL and the voltages of the unselected wordlines V_UNSEL_WL may sequentially decrease from the voltage level L1 to a voltage level EVC and a voltage level IVC.

In some implementations, when the third read command CMD3 is received after the second recovery time interval RCY2, as with that described with reference to FIG. 9A, the third sensing time interval SEN3, the third pending time interval PND3, and the third dump time interval DP3 may be performed. A third setup time interval STP3 may be performed similarly to the first setup time interval STP1 before the third sensing time interval SEN3.

Referring to FIG. 11B, an example where the second read command CMD2 is not received after the reference time interval elapses in a first pending time interval PND1′ is illustrated, as compared to FIG. 9A. The descriptions repeated with or overlapping with descriptions of FIG. 9A will be omitted for brevity.

Since the second read command CMD2 has not been received, the operations corresponding to the second sensing time interval SEN2, the second pending time interval PND2 and the second dump time interval DP2 may not be performed after the first dump time interval DP1. Instead, an operation corresponding to a first recovery time interval RCY1 may be performed after the first dump time interval DP1. In the first recovery time interval RCY1, as the recovery operation is performed, the voltage of the selected string selection line V_SEL_SSL may decrease to the same voltage level as the voltages of the unselected string selection lines V_UNSEL_SSL, and the voltages of the selected wordline V_SEL_WL and the unselected wordlines V_UNSEL_WL may sequentially decrease from the voltage level L1 to the voltage level EVC and the voltage level IVC.

In some implementations, when the second read command CMD2 is received after the first recovery time interval RCY1, as with that described with reference to FIG. 9A, the second sensing time interval SEN2, the second pending time interval PND2, and the second dump time interval DP2 may elapse after the second read command CMD2 is received. A second setup time interval may be performed similarly to the first setup time interval STP1 before the second sensing time interval SEN2.

Although FIGS. 11A and 11B illustrate examples where the second read command CMD2 or the third read command CMD3 is not received after the reference time interval elapses in the examples of FIG. 9A, example implementations are not limited thereto. For example, in the examples of FIGS. 9B, 10A and 10B, when the second read command CMD2 or the third read command CMD3 is not received after the reference time interval elapses, the first recovery time interval RCY1 or the second recovery time interval RCY2 may be performed as with that described with reference to FIGS. 11A and 11B.

Referring to FIG. 12, an example of performing sequential read operations based on read commands CMD3 and CMD4 for TLCs connected to different string selection lines is illustrated. The third read command CMD3 is substantially the same as the third read command CMD3 in FIG. 9A, and read commands CMD1 and CMD2 may be received and executed before the third read command CMD3. The descriptions repeated with or overlapping with descriptions of FIG. 9A will be omitted for brevity.

For example, the third read command CMD3 may be a command for reading the MSB of the data stored in the TLC connected to a first string selection line SSLn (where n is a positive integer). The third sensing time interval SEN3, the third pending time interval PND3 and the third dump time interval DP3 performed based on the third read command CMD3 and a third read address ADDR_MSB_SSLn corresponding to the third read command CMD3 may be similar to that described with reference to FIG. 9A.

For example, the fourth read command CMD4 may be a command for reading the LSB of the data stored in the TLCs connected to a second string selection line SSLn+1 different from the first string selection line SSLn. In the example of FIG. 12, the fourth read command CMD4 is received within the reference time interval in the third pending time interval PND3. Accordingly, the recovery time interval and recovery operation may be omitted.

When the fourth read command CMD4 and a fourth read address ADDR_LSB SSLn+1 corresponding to the fourth read command CMD4 are received, a fourth setup time interval STP4 and a fourth sensing time interval SEN4 are sequentially performed, and although not shown, a fourth pending time interval and a fourth dump time interval may be performed. Since this operation is a sequential read operation for different TLCs and the selected string selection line has been changed, the fourth setup time interval STP4 may be performed. For example, the first string selection line SSLn may be the selected string selection line in the third sensing time interval SEN3, the third pending time interval PND3 and the third dump time interval DP3. The second string selection line SSLn+1 may be the selected string selection line in the fourth setup time interval STP4 and the fourth sensing time interval SEN4. Except for the change in the selected string selection line, the operations in the fourth setup time interval STP4 and the fourth sensing time interval SEN4 may be substantially the same as the operations in the first setup time interval STP1 and the first sensing time interval SEN1 described with reference to FIG. 9A.

In some implementations, at least one of a voltage level and an application time of a prepulse, which is applied to the first string selection line SSLn in the first setup time interval STP1 based on the first read command CMD1, is different from at least one of a voltage level and an application time of a prepulse, which is applied to the second string selection line SSLn+1 in the fourth setup time interval STP4 based on the fourth read command CMD4.

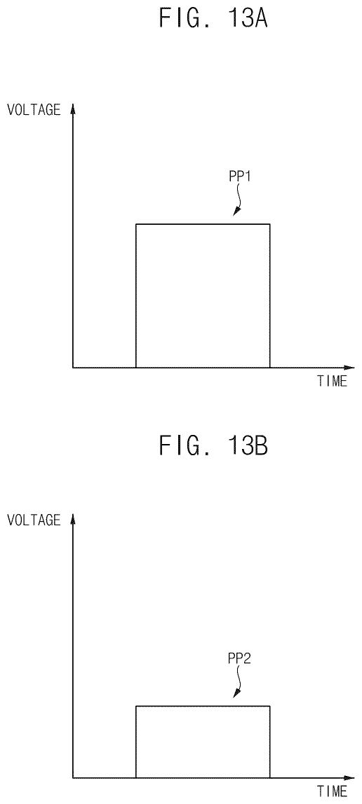

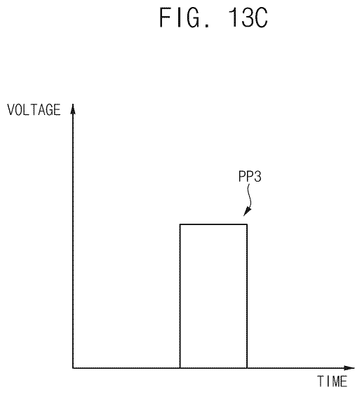

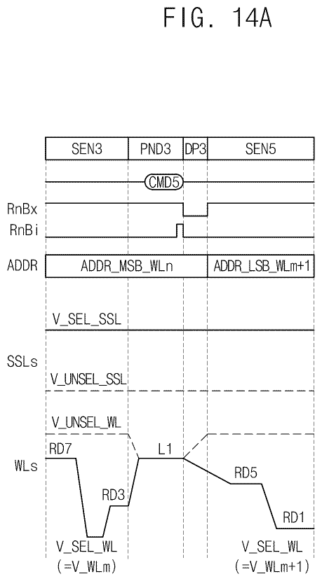

Referring to FIGS. 13A, 13B, and 13C, various examples of the prepulse are illustrated.

Compared to a prepulse PP1 shown in FIG. 13A, a prepulse PP2 shown in FIG. 13B may have a lower voltage level, and a prepulse PP3 shown in FIG. 13C may have a shorter application time. The prepulse PP1 in FIG. 13A may be referred to as a normal prepulse, and prepulses PP2 and PP3 in FIGS. 13B and 13C may be referred to as shallow prepulses. A normal prepulse may be used at the beginning of the operation, and shallow prepulses may be used thereafter.

Although examples are described of decreasing in the voltage level of the prepulse or a shortening of the application time is illustrated, the example implementations are not limited thereto. In some implementations, the voltage level of the prepulse may increase, or the application time may be longer. In addition, although examples where only one of the voltage level and application time of the prepulse is adjusted are described, the example implementations are not limited thereto. In some implementations, both the voltage level and application time of the prepulse may be adjusted.

Referring to FIG. 14A, an example is illustrated where sequential read operations are performed based on read commands CMD3 and CMD5 associated with the TLCs connected to different wordlines. The third read command CMD3 is substantially the same as the third read command CMD3 in FIG. 9A, and read commands CMD1 and CMD2 may be received and executed before the third read command CMD3. The descriptions overlapping with those in FIG. 9A are omitted for brevity.

For example, the third read command CMD3 may be a command for reading the MSB of the data stored in the TLC connected to a first wordline WLm (where m is a positive integer). Based on the third read command CMD3 and a third read address ADDR_MSB_WLm corresponding to the third read command CMD3, the third sensing time interval SEN3, the third pending time interval PND3 and the third dump time interval DP3 may be similar to what is described with reference to FIG. 9A.

For example, the fifth read command CMD5 may be a command for reading the LSB of the data stored in the TLC connected to a second wordline WLm+1 different from the first wordline WLm. In the example of FIG. 14A, the fifth read command CMD5 is received within the reference time interval in the third pending time interval PND3. Accordingly, the recovery time interval and recovery operation may be omitted.

When the fifth read command CMD5 and a fifth read address ADDR_LSB_WLm+1 corresponding to the fifth read command CMD5 are received, a fifth sensing time interval SEN5 is sequentially performed, and although not shown, a fifth pending time interval and a fifth dump time interval may also be performed. Although this operation is a sequential operation for different TLCs, since the selected string selection line has not changed, an operation corresponding to a fifth setup time interval may not be performed. For example, in the third sensing time interval SEN3, the third pending time interval PND3 and the third dump time interval DP3, the first wordline WLm may be the selected wordline, and a voltage of the first wordline V_WLm may be the selected wordline voltage V_SEL_WL, and, in the fifth sensing time interval SEN5, the second wordline WLm+1 may be the selected wordline, and a voltage of the second wordline V_WLm+1 may be the selected wordline voltage V_SEL_WL. Except for the change in the selected wordline, the operation in the fifth sensing time interval SEN5 may be substantially the same as the operation in the first sensing time interval SEN1 of FIG. 9A.

Referring to FIG. 14B, an example where the sequential read operations are performed based on read commands CMD3 and CMD6 for TLCs connected to different string selection lines and different wordlines is illustrated. The descriptions repeated with or overlapping with descriptions of FIG. 9A will be omitted for brevity.

For example, the third read command CMD3 may be a command for reading the MSB of the data stored in the TLC connected to the first string selection line SSLn and the first wordline WLm. The third sensing time interval SEN3, the third pending time interval PND3 and the third dump time interval DP3 performed based on the third read command CMD3 and a third read address ADDR_MSB_SSLn_WLm corresponding to the third read command CMD3 may be similar to what is described with reference to FIG. 9A.

For example, the sixth read command CMD6 may be a command for reading the LSB of the data stored in the TLC connected to the second string selection line SSLn+1 and the second wordline WLm+1. The operation of a sixth setup time interval STP6 and a sixth sensing time interval SEN6 performed based on the sixth read command CMD6 and a sixth read address ADDR_MSB_SSLn+1_WLm+1 corresponding to the sixth read command CMD6 may be substantially the same as the combination of FIG. 12 and FIG. 14A.

Although examples are described based on specific wordlines, specific string selection lines, a specific number of commands and memory cells storing a specific number of bits, example implementations are not limited thereto and may be variously expanded/modified.

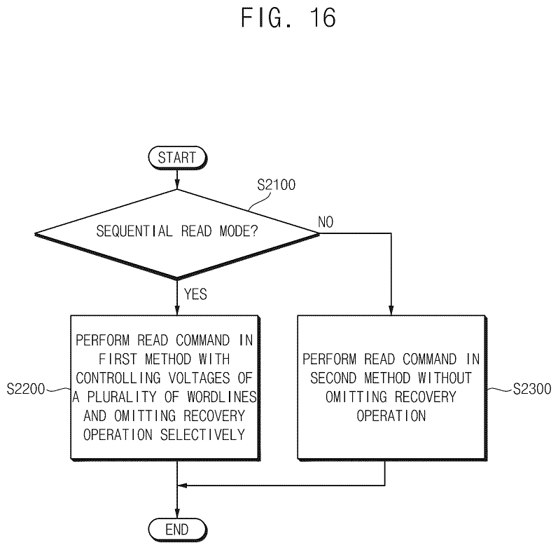

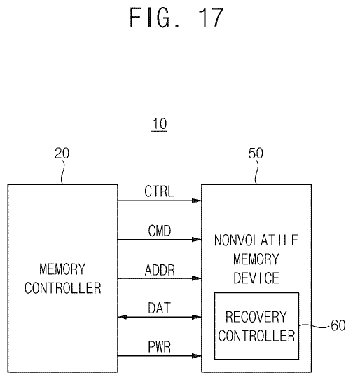

FIGS. 15 and 16 are flowcharts illustrating an example of a method of reading data from a nonvolatile memory device.

Referring to FIG. 15, in the method of reading data from a nonvolatile memory device, the first read command is received (operation S1100), and the first sensing operation is performed based on the first read command (operation S1200). Operation S1200 may be substantially the same as operation S100 of FIG. 1.

Thereafter, by setting the value of K (where K is a positive integer at least 2) to 2 (operation S1250), sequential read operations may be performed while increasing the value of K.

Specifically, while pending the reception of the Kth read command, the voltages of the plurality of wordlines are controlled such that the voltage of the selected wordline and the voltages of the unselected wordlines among the plurality of wordlines have the same voltage level (operation S1300). If the Kth read command is received within the reference time interval (operation S1400: YES), the recovery operation is omitted (operation S1500). If the Kth read command is not received after the reference time interval elapses (operation S1400: NO), the recovery operation may be performed (operation S1600). The Kth sensing operation is performed based on the reception of the Kth read command (operation S1700). Operation S1300 and S1700 may be substantially the same as operations S200 and S400 of FIG. 1, respectively, and operations S1400, S1500 and S1600 may be substantially the same as operations S311, S313 and S315 of FIG. 2, respectively.

Thereafter, it may be determined whether K is the maximum value, which implies that the Kth read command is the last read command (operation S1800). If the Kth read command is not the last read command (operation S1800: NO), K is increased by 1 (operation S1850), and operations S1300, S1400, S1500, S1600, and S1700 may be repeated. If the Kth read command is the last read command (operation S1800: YES), the read process may terminate, and although not shown, the recovery operation may finally be performed.

Referring to FIG. 16, it may be determined whether the operation mode of the nonvolatile memory device is in the sequential read mode in the method of reading data from a nonvolatile memory device (operation S2100).

When the operation mode of the nonvolatile memory device is in the sequential read mode (operation S2100: YES), the read operation may be performed in the first method (operation S2200). For example, in the first method, the voltages of the plurality of wordlines may be controlled such that the voltage of the selected wordline and the voltages of the unselected wordlines have the same voltage level while pending the next read command, and the recovery operation may be omitted when the next read command is received within the reference time interval. For example, operation S2200 may be performed based on the methods described with reference to FIGS. 1 to 15.

When the operation mode of the nonvolatile memory device is not in the sequential read mode (operation S2100: NO), the read operation may be performed in a second method different from the first method (operation S2300). For example, in the second method, the voltages of the plurality of wordlines may not be controlled while pending the next read command, and the recovery operation may not be omitted. For example, operation S2300 may be performed without performing operations S200 and S300 of FIG. 1.

FIG. 17 is a block diagram illustrating an example of a nonvolatile memory device and a memory system including the nonvolatile memory device.

Referring to FIG. 17, a memory system 10 includes a memory controller 20 and the nonvolatile memory device 50.

The nonvolatile memory device 50 may perform the erase, write, and/or read operations of data under the control of the memory controller 20. The nonvolatile memory device 50 may receive the command CMD and the addresses ADDR from the memory controller 20 via the input/output line and may transmit and receive the data DAT for the memory controller 20, program or read operation. In addition, the nonvolatile memory device 50 may receive control signals CTRL through control lines and may be supplied with a power voltage PWR from the memory controller 20 via power lines.

The nonvolatile memory device 50 may be the nonvolatile memory device, include a recovery controller 60, and perform the method of reading data. For example, while pending the reception of the next read command, the voltages of multiple wordlines WL may be controlled, and the recovery operation may be omitted according to the reception condition of the next read command. Accordingly, the amount of time used for the read operation and the latency of the read operation may be reduced, and the read operation may be performed efficiently because the recovery operation does not need to be performed each time the read operation is performed.

In some implementations, some or all of signal lines 30 may be referred to as channels. For example, the data input/output line through which the data DAT is transmitted, the command line through which the command CMD are transmitted and the address line through which the addresses ADDR are transmitted may collectively be referred to as channels.

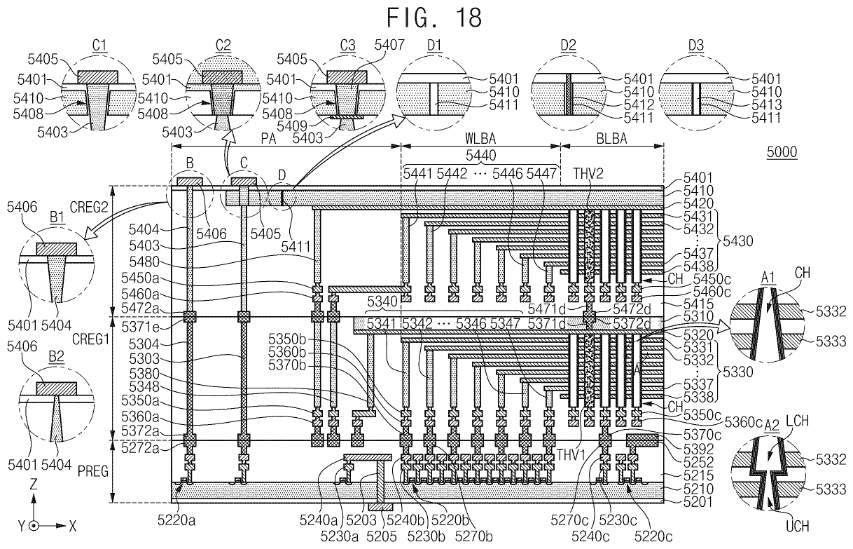

FIG. 18 is a cross-sectional view of an example of a nonvolatile memory device.

Referring to FIG. 18, a memory device (or nonvolatile memory device) 5000 has a chip-to-chip (C2C) structure. At least one upper chip including a cell region and a lower chip including a peripheral circuit region PREG may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu—Cu bonding method. Alternatively, the bonding metal patterns may be formed of aluminum (Al) or tungsten (W).

The memory device 5000 may include the at least one upper chip including the cell region. For example, as illustrated in FIG. 18, the memory device 5000 may include two upper chips. However, the number of the upper chips is not limited thereto. In the case in which the memory device 5000 includes the two upper chips, a first upper chip including a first cell region CREG1, a second upper chip including a second cell region CREG2 and the lower chip including the peripheral circuit region PREG may be manufactured separately, and then, the first upper chip, the second upper chip and the lower chip may be connected to each other by the bonding method to manufacture the memory device 5000. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a −Z-axis direction in FIG. 18. However, example implementations are not limited thereto. In some implementations, one of the first upper chip and the second upper chip may be turned over and then may be connected to a corresponding chip by the bonding method.

Each of the peripheral circuit region PREG and the first and second cell regions CREG1 and CREG2 of the memory device 5000 may include an external pad bonding region PA, a wordline bonding region WLBA, and a bitline bonding region BLBA.

The peripheral circuit region PREG may include a first substrate 5210 and a plurality of circuit elements 5220a, 5220b and 5220c formed on the first substrate 5210. An interlayer insulating layer 5215 including one or more insulating layers may be provided on the plurality of circuit elements 5220a, 5220b and 5220c, and a plurality of metal lines electrically connected to the plurality of circuit elements 5220a, 5220b and 5220c may be provided in the interlayer insulating layer 5215. For example, the plurality of metal lines may include first metal lines 5230a, 5230b and 5230c connected to the plurality of circuit elements 5220a, 5220b and 5220c, and second metal lines 5240a, 5240b and 5240c formed on the first metal lines 5230a, 5230b and 5230c. The plurality of metal lines may be formed of at least one of various conductive materials. For example, the first metal lines 5230a, 5230b and 5230c may be formed of tungsten having a relatively high electrical resistivity, and the second metal lines 5240a, 5240b and 5240c may be formed of copper having a relatively low electrical resistivity.

The first metal lines 5230a, 5230b and 5230c and the second metal lines 5240a, 5240b and 5240c are illustrated and described in some examples. However, example implementations are not limited thereto. In some implementations, at least one or more additional metal lines may further be formed on the second metal lines 5240a, 5240b and 5240c. In this case, the second metal lines 5240a, 5240b and 5240c may be formed of aluminum, and at least some of the additional metal lines formed on the second metal lines 5240a, 5240b and 5240c may be formed of copper having an electrical resistivity lower than that of aluminum of the second metal lines 5240a, 5240b and 5240c.

The interlayer insulating layer 5215 may be disposed on the first substrate 5210 and may include an insulating material such as silicon oxide and/or silicon nitride.

Each of the first and second cell regions CREG1 and CREG2 may include at least one memory block. The first cell region CREG1 may include a second substrate 5310 and a common source line 5320. A plurality of wordlines 5330 (5331 to 5338) may be stacked on the second substrate 5310 in a direction (i.e., the Z-axis direction) perpendicular to a top surface of the second substrate 5310. String selection lines and a ground selection line may be disposed on and under the wordlines 5330, and the plurality of wordlines 5330 may be disposed between the string selection lines and the ground selection line. Likewise, the second cell region CREG2 may include a third substrate 5410 and a common source line 5420, and a plurality of wordlines 5430 (5431 to 5438) may be stacked on the third substrate 5410 in a direction (i.e., the Z-axis direction) perpendicular to a top surface of the third substrate 5410. Each of the second substrate 5310 and the third substrate 5410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CREG1 and CREG2.

In some implementations, as illustrated in a region ‘A1’, the channel structure CH may be provided in the bitline bonding region BLBA and may extend in the direction perpendicular to the top surface of the second substrate 5310 to penetrate the wordlines 5330, the string selection lines, and the ground selection line. The channel structure CH may include a data storage layer, a channel layer, and a filling insulation layer. The channel layer may be electrically connected to a first metal line 5350c and a second metal line 5360c in the bitline bonding region BLBA. For example, the second metal line 5360c may be a bitline and may be connected to the channel structure CH through the first metal line 5350c. The second metal line 5360c may extend in a first direction (e.g., a Y-axis direction) parallel to the top surface of the second substrate 5310.

In some implementations, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 5310 to penetrate the common source line 5320 and lower wordlines 5331 and 5332. The lower channel LCH may include a data storage layer, a channel layer, and a filling insulation layer and may be connected to the upper channel UCH. The upper channel UCH may penetrate upper wordlines 5333 to 5338. The upper channel UCH may include a data storage layer, a channel layer, and a filling insulation layer, and the channel layer of the upper channel UCH may be electrically connected to the first metal line 5350c and the second metal line 5360c. As a length of a channel increases, due to characteristics of manufacturing processes, it may be difficult to form a channel having a substantially uniform width. The memory device 5000 may include a channel having improved width uniformity due to the lower channel LCH and the upper channel UCH which are formed by the processes performed sequentially.

In the case in which the channel structure CH includes the lower channel LCH and the upper channel UCH as illustrated in the region ‘A2’, a wordline located near to a boundary between the lower channel LCH and the upper channel UCH may be a dummy wordline. For example, the wordlines 5332 and 5333 adjacent to the boundary between the lower channel LCH and the upper channel UCH may be the dummy wordlines. In this case, data may not be stored in memory cells connected to the dummy wordline. Alternatively, the number of pages corresponding to the memory cells connected to the dummy wordline may be less than the number of pages corresponding to the memory cells connected to a general wordline. A level of a voltage applied to the dummy wordline may be different from a level of a voltage applied to the general wordline, and thus it is possible to reduce an influence of a non-uniform channel width between the lower and upper channels LCH and UCH on an operation of the memory device.

In some implementations, the number of the lower wordlines 5331 and 5332 penetrated by the lower channel LCH is less than the number of the upper wordlines 5333 to 5338 penetrated by the upper channel UCH in the region ‘A2’. However, example implementations are not limited thereto. In some implementations, the number of lower wordlines penetrated by the lower channel LCH may be equal to or more than the number of upper wordlines penetrated by the upper channel UCH. In addition, structural features and connection relation of the channel structure CH disposed in the second cell region CREG2 may be substantially the same as those of the channel structure CH disposed in the first cell region CREG1.

In the bitline bonding region BLBA, a first through-electrode THV1 may be provided in the first cell region CREG1, and a second through-electrode THV2 may be provided in the second cell region CREG2. As illustrated in FIG. 18, the first through-electrode THV1 may penetrate the common source line 5320 and the plurality of wordlines 5330. In some implementations, the first through-electrode THV1 may further penetrate the second substrate 5310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some implementations, the first through-electrode THV1 and the second through-electrode THV2 may be electrically connected to each other through a first through-metal pattern 5372d and a second through-metal pattern 5472d. The first through-metal pattern 5372d may be formed at a bottom end of the first upper chip including the first cell region CREG1, and the second through-metal pattern 5472d may be formed at a top end of the second upper chip including the second cell region CREG2. The first through-electrode THV1 may be electrically connected to the first metal line 5350c and the second metal line 5360c. A lower via 5371d may be formed between the first through-electrode THV1 and the first through-metal pattern 5372d, and an upper via 5471d may be formed between the second through-electrode THV2 and the second through-metal pattern 5472d. The first through-metal pattern 5372d and the second through-metal pattern 5472d may be connected to each other by the bonding method.

In addition, in the bitline bonding region BLBA, an upper metal pattern 5252 may be formed in an uppermost metal layer of the peripheral circuit region PREG, and an upper metal pattern 5392 having the same shape as the upper metal pattern 5252 may be formed in an uppermost metal layer of the first cell region CREG1. The upper metal pattern 5392 of the first cell region CREG1 and the upper metal pattern 5252 of the peripheral circuit region PREG may be electrically connected to each other by the bonding method. In the bitline bonding region BLBA, the second metal line 5360c may be electrically connected to a page buffer included in the peripheral circuit region PREG. For example, some of the circuit elements 5220c of the peripheral circuit region PREG may constitute the page buffer, and the second metal line 5360c may be electrically connected to the circuit elements 5220c constituting the page buffer through an upper bonding metal pattern 5370c of the first cell region CREG1 and an upper bonding metal pattern 5270c of the peripheral circuit region PREG.

Referring continuously to FIG. 18, in the wordline bonding region WLBA, the wordlines 5330 of the first cell region CREG1 may extend in a second direction (e.g., an X-axis direction) parallel to the top surface of the second substrate 5310 and may be connected to a plurality of cell contact plugs 5340 (contact plugs 5341, 5342 . . . 5346, and 5347). First metal lines 5350b and second metal lines 5360b may be sequentially connected onto the cell contact plugs 5340 connected to the wordlines 5330. In the wordline bonding region WLBA, the cell contact plugs 5340 may be connected to the peripheral circuit region PREG through upper bonding metal patterns 5370b of the first cell region CREG1 and upper bonding metal patterns 5270b of the peripheral circuit region PREG.

The cell contact plugs 5340 may be electrically connected to a row decoder included in the peripheral circuit region PREG. For example, some of the circuit elements 5220b of the peripheral circuit region PREG may constitute the row decoder, and the cell contact plugs 5340 may be electrically connected to the circuit elements 5220b constituting the row decoder through the upper bonding metal patterns 5370b of the first cell region CREG1 and the upper bonding metal patterns 5270b of the peripheral circuit region PREG. In some implementations, an operating voltage of the circuit elements 5220b constituting the row decoder may be different from an operating voltage of the circuit elements 5220c constituting the page buffer. For example, the operating voltage of the circuit elements 5220c constituting the page buffer may be greater than the operating voltage of the circuit elements 5220b constituting the row decoder.

Likewise, in the wordline bonding region WLBA, the wordlines 5430 of the second cell region CREG2 may extend in the second direction (e.g., the X-axis direction) parallel to the top surface of the third substrate 5410 and may be connected to a plurality of cell contact plugs 5440 (5441 to 5447). The cell contact plugs 5440 may be connected to the peripheral circuit region PREG through an upper metal pattern of the second cell region CREG2 and lower and upper metal patterns and a cell contact plug 5348 of the first cell region CREG1.

In the wordline bonding region WLBA, the upper bonding metal patterns 5370b may be formed in the first cell region CREG1, and the upper bonding metal patterns 5270b may be formed in the peripheral circuit region PREG. The upper bonding metal patterns 5370b of the first cell region CREG1 and the upper bonding metal patterns 5270b of the peripheral circuit region PREG may be electrically connected to each other by the bonding method. The upper bonding metal patterns 5370b and the upper bonding metal patterns 5270b may be formed of aluminum, copper, or tungsten.

In the external pad bonding region PA, a lower metal pattern 5371e may be formed in a lower portion of the first cell region CREG1, and an upper metal pattern 5472a may be formed in an upper portion of the second cell region CREG2. The lower metal pattern 5371e of the first cell region CREG1 and the upper metal pattern 5472a of the second cell region CREG2 may be connected to each other by the bonding method in the external pad bonding region PA. Likewise, an upper metal pattern 5372a may be formed in an upper portion of the first cell region CREG1, and an upper metal pattern 5272a may be formed in an upper portion of the peripheral circuit region PREG. The upper metal pattern 5372a of the first cell region CREG1 and the upper metal pattern 5272a of the peripheral circuit region PREG may be connected to each other by the bonding method.

Common source line contact plugs 5380 and 5480 may be disposed in the external pad bonding region PA. The common source line contact plugs 5380 and 5480 may be formed of a conductive material such as a metal, a metal compound, and/or doped polysilicon. The common source line contact plug 5380 of the first cell region CREG1 may be electrically connected to the common source line 5320, and the common source line contact plug 5480 of the second cell region CREG2 may be electrically connected to the common source line 5420. A first metal line 5350a and a second metal line 5360a may be sequentially stacked on the common source line contact plug 5380 of the first cell region CREG1, and a first metal line 5450a and a second metal line 5460a may be sequentially stacked on the common source line contact plug 5480 of the second cell region CREG2.

Input/output pads 5205, 5405 and 5406 may be disposed in the external pad bonding region PA. Referring to FIG. 18, a lower insulating layer 5201 may cover a bottom surface of the first substrate 5210, and a first input/output pad 5205 may be formed on the lower insulating layer 5201. The first input/output pad 5205 may be connected to at least one of a plurality of the circuit elements 5220a disposed in the peripheral circuit region PREG through a first input/output contact plug 5203 and may be separated from the first substrate 5210 by the lower insulating layer 5201. In addition, a side insulating layer may be disposed between the first input/output contact plug 5203 and the first substrate 5210 to electrically isolate the first input/output contact plug 5203 from the first substrate 5210.

An upper insulating layer 5401 covering a top surface of the third substrate 5410 may be formed on the third substrate 5410. A second input/output pad 5405 and/or a third input/output pad 5406 may be disposed on the upper insulating layer 5401. The second input/output pad 5405 may be connected to at least one of the plurality of circuit elements 5220a disposed in the peripheral circuit region PREG through second input/output contact plugs 5403 and 5303, and the third input/output pad 5406 may be connected to at least one of the plurality of circuit elements 5220a disposed in the peripheral circuit region PREG through third input/output contact plugs 5404 and 5304.

In some implementations, the third substrate 5410 may not be disposed in a region in which the input/output contact plug is disposed. For example, as illustrated in a region ‘B’, the third input/output contact plug 5404 may be separated from the third substrate 5410 in a direction parallel to the top surface of the third substrate 5410 and may penetrate an interlayer insulating layer 5415 of the second cell region CREG2 so as to be connected to the third input/output pad 5406. In this case, the third input/output contact plug 5404 may be formed by at least one of various processes.

In some implementations, as illustrated in a region ‘B1’, the third input/output contact plug 5404 may extend in a third direction (e.g., the Z-axis direction), and a diameter of the third input/output contact plug 5404 may become progressively greater toward the upper insulating layer 5401. In other words, a diameter of the channel structure CH described in the region ‘A1’ may become progressively less toward the upper insulating layer 5401, but the diameter of the third input/output contact plug 5404 may become progressively greater toward the upper insulating layer 5401. For example, the third input/output contact plug 5404 may be formed after the second cell region CREG2 and the first cell region CREG1 are bonded to each other by the bonding method.

In some implementations, as illustrated in a region ‘B2’, the third input/output contact plug 5404 may extend in the third direction (e.g., the Z-axis direction), and a diameter of the third input/output contact plug 5404 may become progressively less toward the upper insulating layer 5401. In other words, like the channel structure CH, the diameter of the third input/output contact plug 5404 may become progressively less toward the upper insulating layer 5401. For example, the third input/output contact plug 5404 may be formed together with the cell contact plugs 5440 before the second cell region CREG2 and the first cell region CREG1 are bonded to each other.

In some implementations, the input/output contact plug may overlap with the third substrate 5410. For example, as illustrated in a region ‘C’, the second input/output contact plug 5403 may penetrate the interlayer insulating layer 5415 of the second cell region CREG2 in the third direction (e.g., the Z-axis direction) and may be electrically connected to the second input/output pad 5405 through the third substrate 5410. In this case, a connection structure of the second input/output contact plug 5403 and the second input/output pad 5405 may be realized by various methods.

In some implementations, as illustrated in a region ‘C1’, an opening 5408 may be formed to penetrate the third substrate 5410, and the second input/output contact plug 5403 may be connected directly to the second input/output pad 5405 through the opening 5408 formed in the third substrate 5410. In this case, as illustrated in the region ‘C1’, a diameter of the second input/output contact plug 5403 may become progressively greater toward the second input/output pad 5405. However, example implementations are not limited thereto, and in some implementations, the diameter of the second input/output contact plug 5403 may become progressively less toward the second input/output pad 5405.

In some implementations, as illustrated in a region ‘C2’, the opening 5408 penetrating the third substrate 5410 may be formed, and a contact 5407 may be formed in the opening 5408. An end of the contact 5407 may be connected to the second input/output pad 5405, and another end of the contact 5407 may be connected to the second input/output contact plug 5403. Thus, the second input/output contact plug 5403 may be electrically connected to the second input/output pad 5405 through the contact 5407 in the opening 5408. In this case, as illustrated in the region ‘C2’, a diameter of the contact 5407 may become progressively greater toward the second input/output pad 5405, and a diameter of the second input/output contact plug 5403 may become progressively less toward the second input/output pad 5405. For example, the second input/output contact plug 5403 may be formed together with the cell contact plugs 5440 before the second cell region CREG2 and the first cell region CREG1 are bonded to each other, and the contact 5407 may be formed after the second cell region CREG2 and the first cell region CREG1 are bonded to each other.

In the example illustrated in a region ‘C3’, a stopper 5409 may further be formed on a bottom end of the opening 5408 of the third substrate 5410, as compared with the example of the region ‘C2’. The stopper 5409 may be a metal line formed in the same layer as the common source line 5420. Alternatively, the stopper 5409 may be a metal line formed in the same layer as at least one of the wordlines 5430. The second input/output contact plug 5403 may be electrically connected to the second input/output pad 5405 through the contact 5407 and the stopper 5409.

Like the second and third input/output contact plugs 5403 and 5404 of the second cell region CREG2, a diameter of each of the second and third input/output contact plugs 5303 and 5304 of the first cell region CREG1 may become progressively less toward the lower metal pattern 5371e or may become progressively greater toward the lower metal pattern 5371e.

In some implementations, a slit 5411 may be formed in the third substrate 5410. For example, the slit 5411 may be formed at a certain position of the external pad bonding region PA. For example, as illustrated in a region ‘D’, the slit 5411 may be located between the second input/output pad 5405 and the cell contact plugs 5440 when viewed in a plan view. Alternatively, the second input/output pad 5405 may be located between the slit 5411 and the cell contact plugs 5440 when viewed in a plan view.

In some implementations, as illustrated in a region ‘D1’, the slit 5411 may be formed to penetrate the third substrate 5410. For example, the slit 5411 may be used to prevent the third substrate 5410 from being finely cracked when the opening 5408 is formed. However, example implementations are not limited thereto, and the slit 5411 may be formed to have a depth ranging from about 60% to about 70% of a thickness of the third substrate 5410.

In some implementations, as illustrated in a region ‘D2’, a conductive material 5412 may be formed in the slit 5411. For example, the conductive material 5412 may be used to discharge a leakage current occurring in driving of the circuit elements in the external pad bonding region PA to the outside. In this case, the conductive material 5412 may be connected to an external ground line.

In some implementations, as illustrated in a region ‘D3’, an insulating material 5413 may be formed in the slit 5411. For example, the insulating material 5413 may be used to electrically isolate the second input/output pad 5405 and the second input/output contact plug 5403 disposed in the external pad bonding region PA from the wordline bonding region WLBA. Since the insulating material 5413 is formed in the slit 5411, it is possible to prevent a voltage provided through the second input/output pad 5405 from affecting a metal layer disposed on the third substrate 5410 in the wordline bonding region WLBA.

In some implementations, the first to third input/output pads 5205, 5405 and 5406 may be selectively formed. For example, the memory device 5000 may be realized to include only the first input/output pad 5205 disposed on the first substrate 5210, to include only the second input/output pad 5405 disposed on the third substrate 5410, or to include only the third input/output pad 5406 disposed on the upper insulating layer 5401.

In some implementations, at least one of the second substrate 5310 of the first cell region CREG1 or the third substrate 5410 of the second cell region CREG2 may be used as a sacrificial substrate and may be completely or partially removed before or after a bonding process. An additional layer may be stacked after the removal of the substrate. For example, the second substrate 5310 of the first cell region CREG1 may be removed before or after the bonding process of the peripheral circuit region PREG and the first cell region CREG1, and then, an insulating layer covering a top surface of the common source line 5320 or a conductive layer for connection may be formed. Likewise, the third substrate 5410 of the second cell region CREG2 may be removed before or after the bonding process of the first cell region CREG1 and the second cell region CREG2, and then, the upper insulating layer 5401 covering a top surface of the common source line 5420 or a conductive layer for connection may be formed.

The memory device 5000 may be the nonvolatile memory device, and may perform the method of reading data.

The example implementations may be applied to various electronic devices and systems that include the nonvolatile memory devices. For example, the example implementations may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, etc.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method of reading data from a nonvolatile memory device, the method comprising:
performing a first sensing operation based on a first read command;
while receipt of a second read command is pending, and after performing the first sensing operation based on the first read command, modifying at least one voltage of a plurality of wordlines such that a voltage of a selected wordline of the plurality of wordlines is the same as voltages of unselected wordlines of the plurality of wordlines; and
performing a second sensing operation based on receipt of the second read command without performing a recovery operation, when the second read command is received within a reference time interval.

2. The method of claim 1, wherein modifying the at least one voltage of the plurality of wordlines includes:
decreasing voltage levels of the unselected wordlines from a first voltage level to a second voltage level; and
increasing a voltage level of the selected wordline from a third voltage level to the second voltage level.

3. The method of claim 2, wherein the second voltage level is higher than an initial voltage level of the selected wordline at a beginning of the second sensing operation.

4. The method of claim 2, wherein the second voltage level is lower than an initial voltage level of the selected wordline at a beginning of the second sensing operation.

5. The method of claim 1, wherein a pending time interval during which receipt of the second read command is pending is at least as long as a time interval to stabilize voltage levels of the selected wordline and the unselected wordlines.

6. The method of claim 5, wherein the pending time interval terminates after the time interval to stabilize the voltage levels of the selected wordlines and the unselected wordlines elapses.

7. The method of claim 1, further comprising:
determining that the reference time interval has elapsed without receiving the second read command; and
in response to determining that the reference time interval has elapsed without receiving the second read command, performing the recovery operation.

8. The method of claim 1, wherein the first read command and the second read command are commands for reading from a same memory cell.

9. The method of claim 8, wherein the nonvolatile memory device includes a plurality of memory cells connected to a plurality of wordlines, wherein each memory cell of the plurality of memory cells is configured to store data of at least two bits.

10. The method of claim 1, wherein the first read command and the second read command are commands for reading from different memory cells, wherein the different memory cells are connected to different string selection lines, respectively.

11. The method of claim 10, further comprising:
applying a first prepulse to a first string selection line of the different string selection lines in response to receiving the first read command, and
applying a second prepulse to a second string selection line of the different string selection lines in response to receiving the second read command,
wherein a first voltage level of the first prepulse is different than a second voltage level of the second prepulse, a first application time of the first prepulse is different than a second application time of the second prepulse, or the first voltage level and the second voltage level are different and the first application time and the second application time are different.

12. The method of claim 1, wherein the first read command and the second read command are commands for reading memory cells connected to different wordlines.

13. The method of claim 1, further comprising determining that an operation mode of the nonvolatile memory device is in a sequential read mode.

14. The method of claim 13, wherein modifying the at least one voltage of the plurality of wordlines is performed subsequent to determining that the operation mode is in the sequential read mode.

15. The method of claim 1, further comprising:
while receipt of a third read command is pending after the second read command is received, modifying at least another voltage of the plurality of wordlines such that the voltage of the selected wordline is the same as the voltages of the unselected wordlines;
receiving the third read command; and
performing a third sensing operation based on the third read command without performing the recovery operation, when the third read command is received within the reference time interval.

16. The method of claim 1, wherein the nonvolatile memory device includes a plurality of memory cells connected to the plurality of wordlines, and
wherein the plurality of memory cells are disposed in a vertical direction on a substrate.

17. A nonvolatile memory device comprising:
a memory cell array including a plurality of memory cells connected to a plurality of wordlines;
a voltage generator configured to generate a plurality of driving voltages to be applied to the plurality of wordlines; and
a control circuit configured to:
receive a first read command;
perform a first sensing operation based on the first read command;
while receipt of a second read command is pending after the first read command is received, modify at least one voltage of the plurality of wordlines such that a selected wordline of the plurality of wordlines has the same voltage as unselected wordlines of the plurality of wordlines;
receive the second read command; and
perform a second sensing operation based on the second read command without performing a recovery operation, when the second read command is received within a reference time interval.

18. The nonvolatile memory device of claim 17, wherein the control circuit includes a recovery controller configured to control when execution of the recovery operation occurs.

19. The nonvolatile memory device of claim 17, wherein the plurality of memory cells are configured to form a plurality of cell strings disposed in a vertical direction on a substrate,
wherein the plurality of cell strings are connected to one bitline, and
wherein each cell string of the plurality of cell strings includes at least one string selection transistor, multiple memory cells, and at least one ground selection transistor.

20. A method of reading data from a nonvolatile memory device, the method comprising:
receiving a first read command in a sequential read mode;
performing a first sensing operation based on the first read command;
while receipt of a second read command is pending after the first read command is received, modifying voltages of a plurality of wordlines comprising a selected wordline and unselected wordlines such that a voltage of a selected wordline is the same as voltages of unselected wordlines, wherein modifying the voltages of the plurality of wordlines comprises increasing a voltage level of the selected wordline and decreasing voltage levels of the unselected wordlines;
checking whether the second read command is received; and
subsequent to determining that receipt of the second read command failed to occur after a reference time interval elapses, performing a recovery operation, or
subsequent to determining that the second read command is received during the reference time interval, performing a second sensing operation without performing the recovery operation,
wherein a pending time interval, during which receipt of the second read command is pending, terminates after a time interval to stabilize voltage levels of the selected wordline and the unselected wordlines elapses.
